(19) United States
(12) Patent Application Publication
(10) Pub. No.: US 2025/0029659 A1
(43) Pub. Date: Jan. 23, 2025

(54) THREE-DIMENSIONAL NOR MEMORY DEVICE FOR MULTIPLY-ACCUMULATE OPERATIONS

(71) Applicant: Micron Technology, Inc., Boise, ID (US)

(72) Inventors: Kamal Karda, Boise, ID (US); Hernan Castro, Shingle Springs, CA (US)

(21) Appl. No.: 18/741,633

(22) Filed: Jun. 12, 2024

Related U.S. Application Data
(60) Provisional application No. 63/514,495, filed on Jul. 19, 2023.

(51) Int. Cl. G11C 16/08; G11C 5/06; G11C 16/04

(52) U.S. Cl. CPC G11C 16/08; G11C 5/063; G11C 16/0483

(57) ABSTRACT

Systems, methods, and apparatus related to memory devices that perform multiplication using memory cells. In one approach, a memory cell array has memory cells stacked vertically above a semiconductor substrate. Each memory cell stores a weight. Local digit lines connect to terminals of the memory cells. The local digit lines extend vertically above the substrate. Select transistors connect to the local digit lines. Select lines control the select transistors, and are used to encode an input pattern to multiply by the stored weights. Accumulation circuitry sums output currents from the memory cells. In one example, each memory cell is formed using a transistor that includes a semiconductor layer to provide a horizontal channel. A gate layer (e.g., a gate stack layer) wraps around a circumference of the semiconductor layer. Wordlines apply gate voltages to the transistors. Each wordline has a respective portion that wraps around a circumference of the gate layer of each transistor.

### RELATED APPLICATIONS

The present application claims priority to and the benefit of Prov. U.S. Pat. App. Ser. No. 63/514,495, filed on Jul. 19, 2023, which is hereby incorporated by reference in the present disclosure in its entirety.

### TECHNICAL FIELD

At least some embodiments disclosed herein relate to memory devices in general and more particularly, but not limited to, memory devices having three-dimensional memory cell arrays in a NOR configuration used for performing multiplication and other operations.

### BACKGROUND

Limited memory bandwidth is a significant problem in machine learning systems. For example, DRAM devices used in current systems store large amounts of weights and activations used in deep neural networks (DNNs).

In one example, deep learning machines, such as those supporting processing for convolutional neural networks (CNNs), perform processing to determine a huge number of calculations per second. For example, input/output data, deep learning network training parameters, and intermediate results are constantly fetched from and stored in one or more memory devices (e.g., DRAM). A DRAM type of memory is typically used due to its cost advantages when large storage densities are involved (e.g., storage densities greater than 100 MB). In one example of a deep learning hardware system, a computational unit (e.g., a system-on-chip (SOC), FPGA, CPU, or GPU) is attached to a memory device(s) (e.g., a DRAM device).

Existing computer architectures use processor chips specialized for serial processing and DRAMs optimized for high density memory. The interface between these two devices is a major bottleneck that introduces latency and bandwidth limitations and adds a considerable overhead in power consumption. Memory on-chip is area expensive and it is not possible to add large amounts of memory to the CPU and GPU processors currently used to train and deploy DNNs.

Memory in neural networks is used to store input data, weight parameters and activations as an input propagates through the network. In training, activations from a forward pass must be retained until they can be used to calculate the error gradients in the backwards pass. As an example, a network can have 26 million weight parameters and compute 16 million activations in a forward pass. If a 32-bit floating-point value is used to store each weight and activation, this corresponds to a total storage requirement of 168 MB.

GPUs and other machines need significant memory for the weights and activations of a neural network. GPUs cannot efficiently execute directly the small convolutions used in deep neural networks, so they need significant activation or weight storage. Finally, memory is also required to store input data, temporary values and program instructions. For example, a high performance GPU may need over 7 GB of local DRAM.

Large amounts of storage data cannot be kept on the GPU processor. In many cases, high performance GPU processors may have only 1 KB of memory associated with each of the processor cores that can be read fast enough to saturate the floating-point data path. Thus, at each layer of a DNN, the GPU needs to save the state to external DRAM, load up the next layer of the network, and then reload the data. As a result, the off-chip memory interface suffers the burden of constantly reloading weights and saving and retrieving activations. This significantly slows down training time and increases power consumption.

In one example, image and other sensors are used and generate large amounts of data. It is inefficient to transmit certain types of data from the sensors to general-purpose microprocessors (e.g., central processing units (CPU)) for processing in some applications. For example, it is inefficient to transmit image data from image sensors to microprocessors for image segmentation, object recognition, feature extraction, etc.

Some image processing can include intensive computations involving multiplications of columns or matrices of elements for accumulation. Some specialized circuits have been developed for the acceleration of multiplication and accumulation operations. For example, a multiplier-accumulator (MAC unit) can be implemented using a set of parallel computing logic circuits to achieve a computation performance higher than general-purpose microprocessors.

### BRIEF DESCRIPTION OF THE DRAWINGS

The embodiments are illustrated by way of example and not limitation in the figures of the accompanying drawings in which references indicate similar elements.

FIG. 1 shows an integrated circuit device having an image sensing pixel array, a memory cell array with tiles, and circuits to perform inference computations according to one embodiment.

FIG. 2 shows the computation of a column of weight bits multiplied by a column of input bits to provide an accumulation result according to one embodiment.

FIG. 3 shows a method of computation in an integrated circuit device based on summing output currents from memory cells according to one embodiment.

FIG. 4 shows an analog weight-stationary architecture for matrix vector multiplication (MVM) according to one embodiment.

FIG. 5 shows a three-dimensional memory cell array having floating gate memory cells in a NOR configuration according to one embodiment.

FIG. 6 shows an architecture having resistive random access memory (RRAM) or NOR memory cells arranged in a parallel configuration for performing multiplication according to one embodiment.

FIG. 7 shows memory cells arranged in parallel with current terminals connected to a common global digit line by a select transistor according to one embodiment.

FIG. 8 is a cross-sectional view taken as illustrated in FIG. 9 (indicated by “XX”) and shows a memory device having NOR flash memory cells stacked in a pillar vertically above a semiconductor substrate (not shown) according to one embodiment.

FIG. 9 shows a top view of the memory device of FIG. 8 having multiple pillars of memory cells electrically isolated by one or more dielectric materials according to one embodiment.

FIG. 10 shows exemplary matrices of memory cells with each matrix having multiple tiles, and each tile having multiple pillars according to one embodiment.

FIG. 11 shows a top view of tiles in an exemplary matrix of FIG. 10 according to one embodiment.

FIG. 12 shows a memory device having global digit lines that connect memory cells of different tiles in a memory cell array to accumulation circuitry according to one embodiment.

FIG. 13 shows a top view of the memory device of FIG. 12 according to one embodiment.

FIG. 14 is top view of a memory device having a structure similar to FIG. 9 except that each of the memory cells in each pillar has one of its two current terminals connected to a common local digit line (LDL′) according to one embodiment.

FIG. 15 is a cross-sectional view of a memory device having a structure similar to FIG. 8 except that a portion of memory cells in a pillar have their wordlines electrically shorted together so the memory cells switch on and off as a unit according to one embodiment.

FIGS. 16-18 show exemplary structures (using a simplified block form merely for purposes of illustration) for configuring local digit lines and memory cells of a memory device according to various embodiments.

FIG. 19 shows global digit lines that sum output currents from selected memory cells of tiles in a memory array according to one embodiment.

FIGS. 20-21 show top views of the memory array of FIG. 19 according to various embodiments.

FIG. 22 shows a method for performing multiplication using memory cells located in a selected portion of one or more tiles according to one embodiment.

### DETAILED DESCRIPTION

The following disclosure describes various embodiments for three-dimensional memory cell arrays in a NOR configuration that are used for performing multiplication and other operations in memory devices. The memory device may, for example, store data used by a host device (e.g., a computing device of an autonomous vehicle, or another computing device that accesses data stored in the memory device). In one example, the memory device is a solid-state drive mounted in an electric vehicle.

In one example, selected memory cell tiles are configured dynamically as the computations for a neural network progress (e.g., move from one layer to another layer). For example, these computations include matrix vector multiplication (MVM) for each layer of the neural network. The weights for the neural network are stored in the memory cell array and multiplication using the weights is performed in the memory cell array itself based on output currents from memory cells in the array. The output currents are digitized and used by a controller to support the MVM.

Improved power efficiency is particularly desirable for use of neural networks on mobile devices and automobiles. Storing the weights for a neural network in the memory device and doing the multiplication in the memory device avoids or reduces the need to move the weights to a central processing unit or other processing device. This reduces the power consumption required to move data to and from memory, and also reduces the memory bandwidth problem described herein.

Various memory device structures may be used for forming a memory cell array. For example, several hardware accelerators based on in-memory compute are can use SRAM, RRAM, or NAND flash memory. However, energy efficiency (power) remains a major bottleneck for inference applications even if using these exemplary accelerators. Further, planar NOR-based schemes exhibit lower density.

More generally, neural networks are one of the most popular classes of machine learning algorithm (e.g., modeled after our understanding of how the brain works). For example, a network has a large number of neurons that on their own perform fairly simple computations, but together can learn complex and non-linear functions. For example, neuron computation is basically multiplication of multiple input values by neuron weights (which represent how important each input is to the computation), and summing of the results. The weights are learned during network training. Each result is then passed through a non-linear activation function to allow the neuron to learn complex relationships.

In terms of computational burden, the multiplication of all input values by neuron weights for all neurons in the network is the most demanding use of processing power. For example, this multiplication can be 90% or more of the computational requirement, depending on the network design. When scaled to a full layer of the neural network, the computation is vectorized and becomes a matrix vector multiplication problem. The computations are also sometimes referred to as dot product or sum-of-products (SOP) computations.

Deep learning technologies are an exemplary implementation of neural networks and have been playing a significant role in a variety of applications such as image classification, object detection, speech recognition, natural language processing, recommender systems, automatic generation, and robotics etc. Many domain-specific deep learning accelerators (DLA) (e.g., GPU, TPU and embedded NPU), have been introduced to provide the required efficient implementations of deep neural networks (DNN) from cloud to edge. However, the limited memory bandwidth is still a critical challenge due to frequent data movement back and forth between compute units and memory in deep learning, especially for energy constrained systems and applications (e.g., edge AIs).

Conventional Von-Neumann computer architecture has developed with processor chips specialized for serial processing and DRAMs optimized for high density memory. The interface between these two devices is a major bottleneck that introduces latency and bandwidth limitations and adds a considerable overhead in power consumption. With the growing demand of higher accuracy and higher speed for Al applications, larger DNN models are developed and implemented with huge amounts of weights and activations. The resulting bottlenecks of memory bandwidth and power consumption on inter-chip data movement are significant technical problems.

Over time, neural networks continue to grow exponentially in complexity, which means there are many more computations required. This stresses the performance of traditional computation architectures. For example, purpose-built compute blocks are needed for the MVM operation to meet performance requirements (GPUs, Digital Accelerators). Also, neuron weights must be fetched from memory, which both causes performance bottlenecks, and is energy inefficient, as mentioned above.

In some cases, the precision of the computations can be reduced to address these concerns. For example, the selection of the type of neural network training can enable roughly equivalent neural network accuracy with significantly lower precision. The lower precision can improve the performance and/or energy efficiency of a neural network implementation. Also, the use of a lower precision can be supportive of storing weights in memory and performing multiplication in the memory, as described herein.

A neural network design itself typically dictates the size of the MVM operation at every layer of the network. Each layer can have a different number of features and neurons. In one embodiment, the MVM computation will take place in a portion of a memory array. This portion is represented in the array as one or more selected tiles.

To address these and other technical problems, a memory device integrates memory and processing. In one example, memory and inference computation processing are integrated in the same integrated circuit device. In some embodiments, the memory device is an integrated circuit device having an image sensing pixel array, a memory cell array, and one or more circuits to use the memory cell array to perform inference computation on image data from image sensors. In some embodiments, the memory device includes or is used with other types of sensors (e.g., LIDAR, radar, sound).

Existing methods of matrix vector multiplication use digital logic gates. Digital logic implementations are more complex, consume more silicon area, and dissipate more power as compared to various embodiments described below. These embodiments effectively reduce the multiplication to a memory access function which can be parallelized in an array. The accumulation function is carried out by wires that connect these memory elements, which can also be parallelized in an array. By combining these two features in an array, matrix vector multiplication can be performed more efficiently than methods using digital logic gates.

In one embodiment, a three-dimensional NOR-based accelerator is used to perform multiply accumulate (MAC) to mitigate challenges with power consumption. For example, this approach significantly increases tera operations per watt (TOPS/W) and improves energy efficiency (e.g., by 5-10 times or more).

In one embodiment, an image sensor is configured with an analog capability to support inference computations by using matrix vector multiplication, such as computations of an artificial neural network. The image sensor can be implemented as an integrated circuit device having an image sensor chip and a memory chip. The memory chip can have a 3D memory array configured to support multiplication and accumulation operations. The integrated circuit device includes one or more logic circuits configured to process images from the image sensor chip, and to operate the memory cells in the memory chip to perform multiplications and accumulation operations.

The memory chip can have multiple layers of memory cells. Each memory cell can be programmed to store a bit of a binary representation of an integer weight. Each input line can be applied a voltage according to a bit of an integer. Columns of memory cells can be used to store bits of a weight matrix; and a set of input lines can be used to control voltage drivers to apply read voltages on rows of memory cells according to bits of an input vector.

The threshold voltage or state of a memory cell used for multiplication and accumulation operations can be programmed such that the current going through the memory cell subjected to a predetermined read voltage is either a predetermined amount representing a value of one stored in the memory cell, or negligible to represent a value of zero stored in the memory cell. When the predetermined read voltage is not applied, the current going through the memory cell is negligible regardless of the value stored in the memory cell. As a result of the configuration, the current going through the memory cell corresponds to the result of a 1-bit weight, as stored in the memory cell, multiplied by a 1-bit input, corresponding to the presence or the absence of the predetermined read voltage driven by a voltage driver controlled by the 1-bit input.

Output currents of the memory cells, representing the results of a column of 1-bit weights stored in the memory cells and multiplied by a column of 1-bit inputs respectively, are connected to a common line (e.g., a global digit line or GDL) for summation. The summed current in the common line is a multiple of the predetermined amount; and the multiples can be digitized and determined using an analog to digital converter or other digitizer. Such results of 1-bit to 1-bit multiplications and accumulations can be performed for different significant bits of weights and different significant bits of inputs. The results for different significant bits can be shifted (e.g., left shifted) to apply the weights of the respective significant bits for summation to obtain the results of multiplications of multi-bit weights and multi-bit inputs with accumulation.

Using the capability of performing multiplication and accumulation operations implemented via memory cell arrays, a logic circuit can be configured to perform inference computations, such as the computation of an artificial neural network.

In one embodiment, a three-dimensional NOR memory device includes a memory cell array having memory cells stacked vertically (e.g., in vertical pillars having multiple tiers). Each memory cell stores a weight for use in a multiplication (e.g., MVM) or other operation. Local digit lines are connected to current terminals of the memory cells. The local digit lines extend vertically above a semiconductor substrate. Select transistors are connected to the local digit lines. Select lines are used to control the select transistors, and to encode an input pattern to multiply by the stored weights. Accumulation circuitry accumulates output currents from the memory cells to determine a result of the multiplication.

In one embodiment, a three-dimensional NOR memory device includes a memory cell array having memory cells stacked vertically above a semiconductor substrate. Each memory cell stores a weight for use in a multiplication or other operation. Each memory cell has a current channel extending in a horizontal direction (parallel with the top surface of the semiconductor substrate). Wordlines are connected to gates of the memory cells. The wordlines are used to encode an input pattern to multiply by the stored weights. Accumulation circuitry accumulates output currents from the memory cells to determine a result of the multiplication.

In one embodiment, a memory device includes a semiconductor substrate, and transistors stacked vertically in pillars above the substrate. Each transistor has a semiconductor layer to provide a channel, and a gate layer (e.g., ONO stack) that wraps around at least half or all of a circumference of the semiconductor layer. Wordlines are used to apply gate voltages to the transistors. In one embodiment, a portion of each wordline wraps around at least half of a circumference of the gate layer of each transistor. In one example, the wordline wraps fully around the gate layer of each transistor.

Various embodiments of memory devices performing multiplication using logical states of memory cells are now described below. A memory device typically has memory cells configured in an array, with each memory cell programmed, for example, to allow an amount of current to go through when a voltage is applied in a predetermined voltage region to represent a first logic state (e.g., a first value stored in the memory cell), or a negligible amount of current to represent a second logic state (e.g., a second value stored the memory cell).

The memory device performs computations based on applying voltages in a digital fashion, in the form of whether or not to apply an input voltage to generate currents for summation over a line (e.g., a bitline of a memory array). The total current on the line will be the multiple of the amount of current allowed for cells programmed at the first value. In one example, an analog-to-digital converter is used to convert the current to a digital result of a sum of bit-by-bit multiplications.

The memory cells in the array are NOR flash memory cells. In one example, floating gate or charge trap memory devices in NOR memory configurations are used.

In one embodiment, a memory device (e.g., integrated circuit device 101) includes a memory cell array having memory cells. Each memory cell is programmable to store a respective weight for performing a multiplication. The integrated circuit device also includes voltage drivers configured to apply input voltages to the memory cells for performing the multiplication. The input voltages represent an input to be multiplied by the respective weight for each memory cell.

The integrated circuit device has a common line coupled to the memory cells. The common line is configured to sum output currents from each of the memory cells that result from applying the input voltages. The integrated circuit device has a digitizer configured to generate a result for the multiplication based on the summed output currents.

In one embodiment, a memory device implements unsigned 1-bit to 1-bit multiplication. Each memory cell can be programmed to a “1-state” such that a predetermined amount of current can go through the memory cell when a voltage V is applied across the memory cell (e.g., across two terminals of a memory cell). Alternatively, the memory cell can be programmed to a “0-state” such that only a negligible amount of current can go through the memory cell when the same voltage V is applied. Thus, the memory cells can be programmed to the “1-state” or the “0-state” to represent a stored weight of “1” or “0” respectively.

An input voltage of V can be used to represent an input of “1”; and an input voltage of 0 can be used to represent an input of “0”. Alternatively, another voltage can be used to represent an input of “0” when the voltage is lower than V but only causes a negligible amount of current to go through the memory cell (regardless of the programmed state of the memory cell).

When a voltage configured to be representative of an input of either 1 or 0 as described above is applied on the memory cell, programmed to either the “1-state” or “0-state” to represent a weight of 1 or 0 as discussed above, the amount of current going through the memory cell is either the predetermined amount (representative of an output of “1”), or a negligible amount (representative of an output of “0”). Further, the input, weight and output relations satisfy the multiplication of a 1-bit input by a 1-bit weight to generate a 1-bit output in all possible variations of input and weight.

Thus, a memory cell is used to perform unsigned 1-bit to multi-bit multiplication via being programed to store a 1-bit weight, applying an input voltage to represent a 1-bit input, and to determine a 1-bit output from sensing whether the current going through the memory cell (the output current from the memory cell) is the predetermined amount.

Summation of results represented by output currents from memory cells can be implemented via connecting the currents to a common line (e.g., a local digit line or global digit line). The summation of results can be digitized to provide a digital output. In one example, an analog-to-digital converter is used to measure the sum as the multiple of the predetermined amount of current and to provide a digital output.

In one embodiment, a memory device implements unsigned 1-bit to multi-bit multiplication. A multi-bit weight can be implemented via multiple memory cells. Each of the memory cells is configured to store one of the bits of the multi-bit weight, as just described above. A voltage represented by a 1-bit input can be applied to the multiple memory cells separately to obtain results of unsigned 1-bit to 1-bit multiplication as described above.

In one embodiment, each memory cell has a position corresponding to its stored bit in the binary representation of the multi-bit weight. Its digitized output (e.g., from the summing of output currents from memory cells on a common line) can be shifted left according to its position in the binary representation to obtain a shifted result. For example, the digitized output of the memory cell storing the least significant bit of the multi-bit weight is shifted by 0 bit; the digitized output of the memory cell storing the second least significant bit of the multi-bit weight is shifted by 1 bit; the digitized output of the memory cell storing the third least significant bit of the multi-bit weight is shifted by 2 bit; etc. The shifted results can be summed to obtain the result of the 1-bit input multiplied by the multi-bit weight stored in the multiple memory cells.

Summation of results represented by output currents from sets of memory cells, each set representing a separate multi-bit weight, can be summed bitwise, via currents connected in common lines, for the different bit positions in multi-bit weights. For example, the currents from memory cells storing the least significant bit are connected to a first common line to form the summed output of results derived from the least significant bits; the currents from memory cells storing the second least significant bit are connected to a second common line to form the summed output of results derived from the second least significant bits; the currents from memory cells storing the third least significant bit are connected to a third common line to form the summed output of results derived from the third least significant bits; etc. The summed outputs can be converted to a digital form, and then shifted for summation in a digital form. Alternatively, the respective currents may be scaled prior to digitization.

In one embodiment, a memory device implements time-sliced unsigned multi-bit to multi-bit multiplication. An input represented by a binary number having a predetermined number of bits (e.g., 4 bits) can be applied one bit at a time through the same predetermined number of clock cycles (e.g., applied at time instances T0, T1, T2, etc.). Each cycle produces an output as described above for unsigned 1-bit to multi-bit multiplication.

The result of the unsigned 1-bit to multi-bit multiplication (e.g., as discussed above) obtained for each clock cycle can be shifted left according to the position of the bit of the input applied in the clock cycle. For example, the result of the clock cycle that applies the least significant bit of the input is not shifted; the result for the second least significant bit is shifted left by 1 bit; the result for the third least significant bit is shifted left by 2 bits; etc. The shifted results from the clock cycles are summed in a digital form.

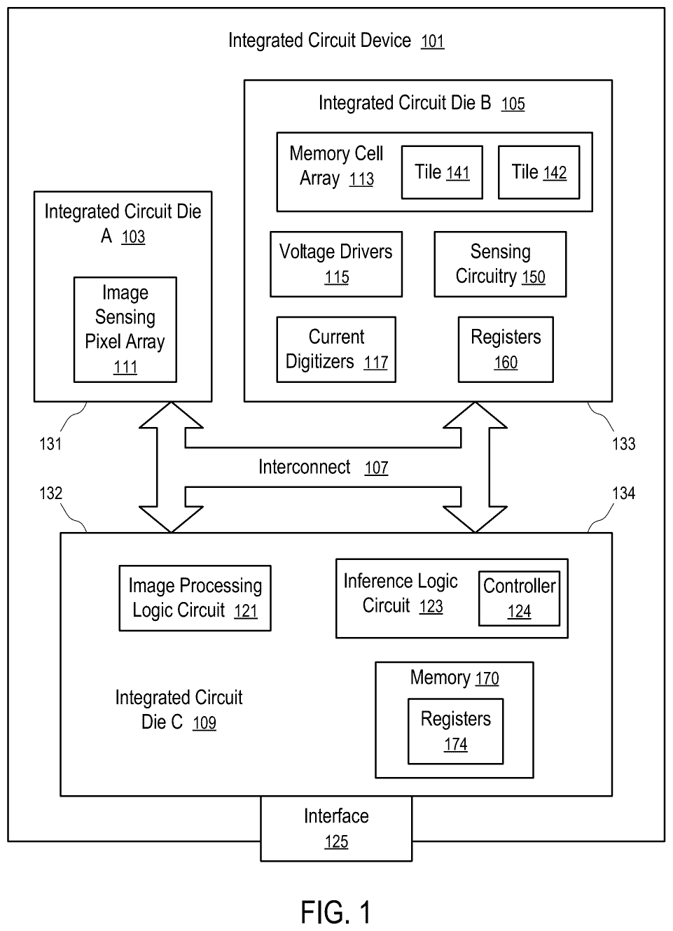

FIG. 1 shows an integrated circuit device 101 having an image sensing pixel array 111, a memory cell array 113 with tiles 141 and 142, and circuits to perform inference computations according to one embodiment. In FIG. 1, the integrated circuit device 101 has an integrated circuit die 109 having logic circuits 121 and 123, an integrated circuit die 103 having the image sensing pixel array 111, and an integrated circuit die 105 having a memory cell array 113.

In one example, memory cell array 113 includes NOR flash memory cells. The memory cells are stacked vertically in the pillars. Each transistor uses a semiconductor layer to provide a channel extending in a horizontal direction relative to the vertical pillars. Each transistor has a gate layer (e.g., ONO stack) that wraps around the outside circumference of the semiconductor layer. Wordlines (e.g., WL1, WL2) are used to apply gate voltages to the transistors. A portion of each wordline wraps around the outside circumference of the gate layer of each transistor. Isolation layers electrically separate the wordlines associated with each transistor in a given pillar. The pillars extend vertically above a semiconductor substrate. The channel extends in a horizontal direction relative to the substrate.

In one example, the integrated circuit die 109 having logic circuits 121 and 123 is a logic chip; the integrated circuit die 103 having the image sensing pixel array 111 is an image sensor chip; and the integrated circuit die 105 having the memory cell array 113 is a memory chip.

In FIG. 1, the integrated circuit die 105 having the memory cell array 113 further includes voltage drivers 115 and current digitizers 117 (e.g., accumulation circuitry to generate digital results from MVM). For example, voltage drivers 115 apply voltages to wordlines (e.g., WL1, WL2) to apply gate voltages to transistors of NOR flash memory cells.

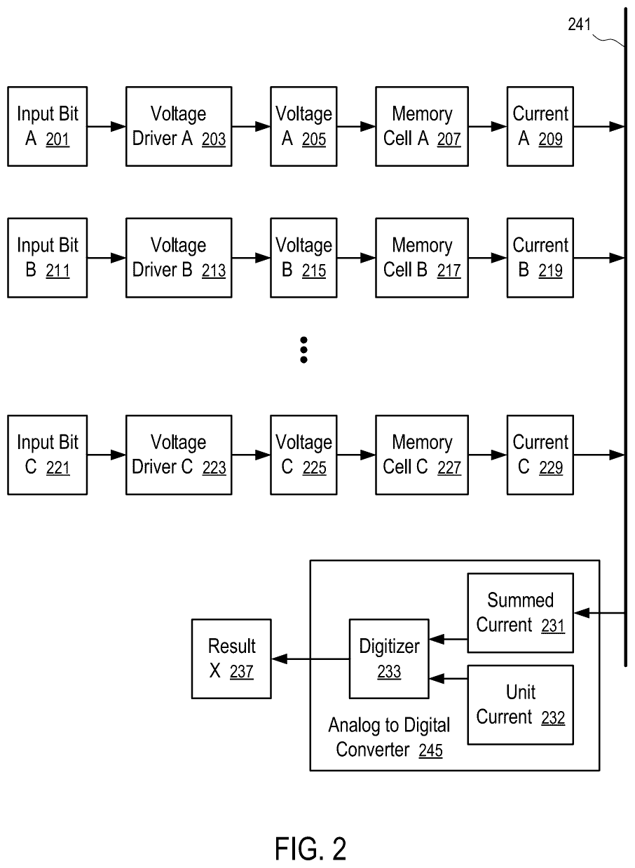

The memory cell array 113 is connected such that currents generated by the memory cells in response to voltages applied by the voltage drivers 115 are summed in the array 113 for columns of memory cells (e.g., as illustrated in FIG. 2); and the summed currents are digitized to generate the sum of bit-wise multiplications. The inference logic circuit 123 can be configured to instruct the voltage drivers 115 to apply read voltages according to a column of inputs, and perform shifts and summations to generate the results of a column or matrix of weights multiplied by the column of inputs with accumulation.

In one embodiment, sensing circuitry 150 is coupled to memory cells in tiles 141, 142. Sensing circuitry 150 is used to sense one or more characteristics of the memory cells. In one embodiment, sensing circuitry 150 includes circuitry to precharge bitlines of tiles 141, 142. Sensing circuitry 150 is configured to receive signals from controller 124 and/or read registers 160 to determine bitlines that will be disabled. In one embodiment, sensing circuitry 150 includes ADCs or other digitizers to convert sums of output currents from memory cells that are accumulated on enabled access lines (e.g., accumulated on enabled bitlines) to provide digital results (e.g., accumulation results).

The inference logic circuit 123 can be further configured to perform inference computations according to weights stored in the memory cell array 113 (e.g., the computation of an artificial neural network) and inputs derived from the image data generated by the image sensing pixel array 111. Optionally, the inference logic circuit 123 can include a programmable processor that can execute a set of instructions to control the inference computation. Alternatively, the inference computation is configured for a particular artificial neural network with certain aspects adjustable via weights stored in the memory cell array 113. Optionally, the inference logic circuit 123 is implemented via an application-specific integrated circuit (ASIC), a field-programmable gate array (FPGA), or a core of a programmable microprocessor.

In one embodiment, inference logic circuit 123 includes controller 124. In one example, controller 124 manages communications with a host system via interface 125. In one example, controller 124 performs signed or unsigned multiplication using memory cell array 113. In one embodiment, controller 124 selects either of signed or unsigned multiplication to be performed based on the type of data to be used as an input for the multiplication. In one example, controller 124 selects signed multiplication in response to determining that inputs for the multiplication are signed.

In FIG. 1, the integrated circuit die 105 having the memory cell array 113 has a bottom surface 133; and the integrated circuit die 109 having the inference logic circuit 123 has a portion of a top surface 134. The two surfaces 133 and 134 can be connected via bonding (e.g., using hybrid bonding) to provide a portion of an interconnect 107 between metal portions on the surfaces 133 and 134.

Similarly, the integrated circuit die 103 having the image sensing pixel array 111 has a bottom surface 131; and the integrated circuit die 109 having the inference logic circuit 123 has another portion of its top surface 132. The two surfaces 131 and 132 can be connected via bonding (e.g., using hybrid bonding) to provide a portion of the interconnect 107 between metal portions on the surfaces 131 and 132.

An image sensing pixel in the array 111 can include a light sensitive element configured to generate a signal responsive to intensity of light received in the element. For example, an image sensing pixel implemented using a complementary metal-oxide-semiconductor (CMOS) technique or a charge-coupled device (CCD) technique can be used.

In some implementations, the image processing logic circuit 121 is configured to pre-process an image from the image sensing pixel array 111 to provide a processed image as an input to the inference computation controlled by the inference logic circuit 123. Optionally, the image processing logic circuit 121 can also use the multiplication and accumulation function provided via the memory cell array 113.

In some implementations, interconnect 107 includes wires for writing image data from the image sensing pixel array 111 to a portion of the memory cell array 113 for further processing by the image processing logic circuit 121 or the inference logic circuit 123, or for retrieval via an interface 125. The inference logic circuit 123 can buffer the result of inference computations in a portion of the memory cell array 113.

The interface 125 of the integrated circuit device 101 can be configured to support a memory access protocol, or a storage access protocol or any combination thereof. Thus, an external device (e.g., a processor, a central processing unit) can send commands to the interface 125 to access the storage capacity provided by the memory cell array 113.

For example, the interface 125 can be configured to support a connection and communication protocol on a computer bus, such as a peripheral component interconnect express (PCIe) bus, a serial advanced technology attachment (SATA) bus, a universal serial bus (USB) bus, a compute express link, etc. In some embodiments, the interface 125 can be configured to include an interface of a solid-state drive (SSD), such as a ball grid array (BGA) SSD. In some embodiments, the interface 125 is configured to include an interface of a memory module, such as a double data rate (DDR) memory module, a dual in-line memory module, etc. The interface 125 can be configured to support a communication protocol such as a protocol according to non-volatile memory express (NVMe), non-volatile memory host controller interface specification (NVMHCIS), etc.

The integrated circuit device 101 can appear to be a memory sub-system from the point of view of a device in communication with the interface 125. Through the interface 125, an external device (e.g., a processor, a central processing unit) can access the storage capacity of the memory cell array 113. For example, the external device can store and update weight matrices and instructions for the inference logic circuit 123, retrieve images generated by the image sensing pixel array 111 and processed by the image processing logic circuit 121, and retrieve results of inference computations controlled by the inference logic circuit 123.

Integrated circuit die 105 includes registers 160. Integrated circuit die 109 includes memory 170 including registers 174. In one embodiment, configuration data from a host is received via interface 125. In one example, the configuration data is data used to set registers 174 and/or 160. The configuration data corresponds to a processing step being done for a neural network. The processing includes MVM computations mapped to tiles 141, 142.

In FIG. 1, the interface 125 is positioned, for example, at the bottom side of the integrated circuit device 101, while the image sensor chip is positioned at the top side of the integrated device 101 to receive incident light for generating images.

The voltage drivers 115 in FIG. 1 can be controlled to apply voltages to program the threshold voltages of memory cells in the array 113. Data stored in the memory cells can be represented by the levels of the programmed threshold voltages of the memory cells.

In one example, the interface 125 can be operable for a host system to write data into the memory cell array 113 and to read data from the memory cell array 113. For example, the host system can send commands to the interface 125 to write the weight matrices of the artificial neural network into the memory cell array 113 and read the output of the artificial neural network, the raw image data from the image sensing pixel array 111, or the processed image data from the image processing logic circuit 121, or any combination thereof.

The inference logic circuit 123 can be programmable and include a programmable processor, an application-specific integrated circuit (ASIC), or a field-programmable gate array (FPGA), or any combination thereof. Instructions for implementing the computations of the artificial neural network can also be written via the interface 125 into the memory cell array 113 for execution by the inference logic circuit 123.

FIG. 2 shows the computation of a column of weight bits multiplied by a column of input bits to provide an accumulation result according to one embodiment. In FIG. 2, a column of memory cells 207, 217, . . . , 227 (e.g., in the memory cell array 113 of an integrated circuit device 101) can be programmed to have threshold voltages at levels representative of weights stored one bit per memory cell.

Voltage drivers 203, 213, . . . , 223 (e.g., in the voltage drivers 115 of an integrated circuit device 101) are configured to apply voltages 205, 215, . . . , 225 to the memory cells 207, 217, . . . , 227 respectively according to their received input bits 201, 211, . . . , 221.

For example, when the input bit 201 has a value of one, the voltage driver 203 applies the predetermined read voltage as the voltage 205, causing the memory cell 207 to output the predetermined amount of current as its output current 209 if the memory cell 207 has a threshold voltage programmed at a lower level, which is lower than the predetermined read voltage, to represent a stored weight of one, or to output a negligible amount of current as its output current 209 if the memory cell 207 has a threshold voltage programmed at a higher level, which is higher than the predetermined read voltage, to represent a stored weight of zero.

However, when the input bit 201 has a value of zero, the voltage driver 203 applies a voltage (e.g., zero) lower than the lower level of threshold voltage as the voltage 205 (e.g., does not apply the predetermined read voltage), causing the memory cell 207 to output a negligible amount of current at its output current 209 regardless of the weight stored in the memory cell 207. Thus, the output current 209 as a multiple of the predetermined amount of current is representative of the result of the weight bit, stored in the memory cell 207, multiplied by the input bit 201.

Similarly, the current 219 going through the memory cell 217 as a multiple of the predetermined amount of current is representative of the result of the weight bit, stored in the memory cell 217, multiplied by the input bit 211; and the current 229 going through the memory cell 227 as a multiple of the predetermined amount of current is representative of the result of the weight bit, stored in the memory cell 227, multiplied by the input bit 221.

The output currents 209, 219, . . . , and 229 of the memory cells 207, 217, . . . , 227 are connected to a common line 241 (e.g., a bitline or source line in tile 141) for summation. In one example, common line 241 is a bitline. A constant voltage (e.g., ground or −1 V) is maintained on the bitline when summing the output currents.

The summed current 231 is compared to the unit current 232, which is equal to the predetermined amount of current, by a digitizer 233 of an analog to digital converter 245 to determine the digital result 237 of the column of weight bits, stored in the memory cells 207, 217, . . . , 227 respectively, multiplied by the column of input bits 201, 211, . . . , 221 respectively with the summation of the results of multiplications.

The sum of negligible amounts of currents from memory cells connected to the line 241 is small when compared to the unit current 232 (e.g., the predetermined amount of current). Thus, the presence of the negligible amounts of currents from memory cells does not alter the result 237 and is negligible in the operation of the analog to digital converter 245.

In FIG. 2, the voltages 205, 215, . . . , 225 applied to the memory cells 207, 217, . . . , 227 are representative of digitized input bits 201, 211, . . . , 221; the memory cells 207, 217, . . . , 227 are programmed to store digitized weight bits; and the currents 209, 219, . . . , 229 are representative of digitized results.

The result 237 is an integer that is no larger than the count of memory cells 207, 217, . . . , 227 connected to the line 241. The digitized form of the output currents 209, 219, . . . , 229 can increase the accuracy and reliability of the computation implemented using the memory cells 207, 217, . . . , 227.

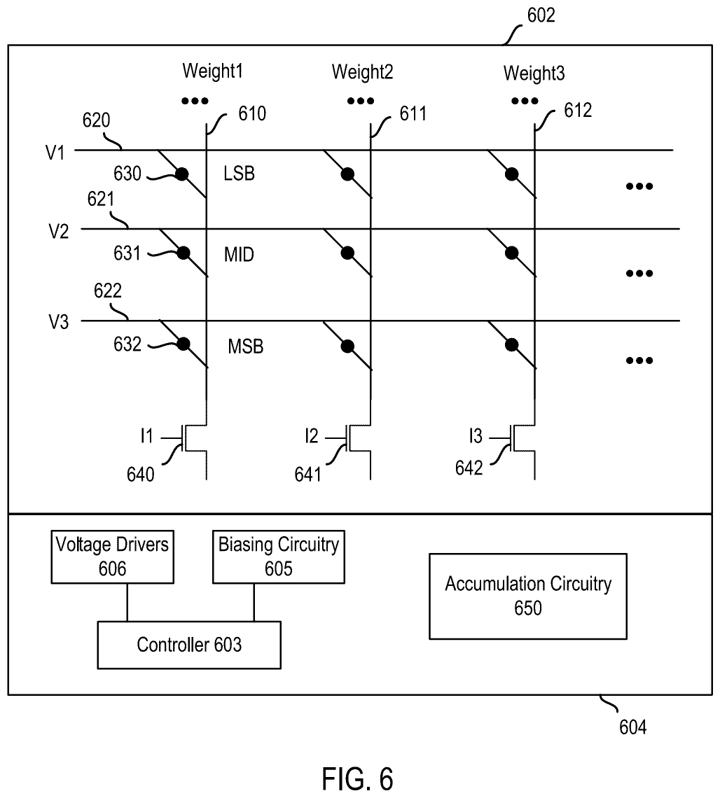

In general, a weight involving a multiplication and accumulation operation can be more than one bit. Memory cells can be used to store the different significant bits of weights (e.g., as illustrated in FIG. 6) to perform multiplication and accumulation operations. The circuit illustrated in FIG. 2 can be considered a multiplier-accumulator unit configured to operate on a column of 1-bit weights and a column of 1-bit inputs. Multiple such circuits can be connected in parallel to implement a multiplier-accumulator unit to operate on a column of multi-bit weights and a column of 1-bit inputs.

The circuit illustrated in FIG. 2 can also be used to read the data stored in the memory cells 207, 217, . . . , 227. For example, sensing circuitry 150 can be used to sense a current associated with a memory cell. For example, to read the data or weight stored in the memory cell 207, the input bits 211, . . . , 221 can be set to zero to cause the memory cells 217, . . . , 227 to output a negligible amount of currents into the line 241 (e.g., as a bitline). The input bit 201 is set to one to cause the voltage driver 203 to apply the predetermined read voltage. Thus, the result 237 from the digitizer 233 provides the data or weight stored in the memory cell 207. Similarly, the data or weight stored in the memory cell 217 can be read via applying one as the input bit 211 and zeros as the remaining input bits in the column; and data or weight stored in the memory cell 227 can be read via applying one as the input bit 221 and zeros as the other input bits in the column.

In general, the circuit illustrated in FIG. 2 can be used to select any of the memory cells 207, 217, . . . , 227 for read or write. A voltage driver (e.g., 203) can apply a programming voltage pulse (e.g., one or more pulses or other waveform, as appropriate for a memory cell type) to adjust the threshold voltage of a respective memory cell (e.g., 207) to erase data, to store data or a weight, etc.

In general, an input involving a multiplication and accumulation operation can be more than 1 bit. For example, columns of input bits can be applied one column at a time to the weights stored in an array of memory cells to obtain the result of a column of weights multiplied by a column of inputs with results accumulated.

The multiplier-accumulator unit illustrated in FIG. 2 can be implemented in integrated circuit device 101 in FIG. 1.

In one implementation, a memory chip (e.g., integrated circuit die 105) includes circuits of voltage drivers, digitizers, shifters, and adders to perform the operations of multiplication and accumulation. The memory chip can further include control logic configured to control the operations of the drivers, digitizers, shifters, and adders to perform the operations as in FIG. 2.

The inference logic circuit 123 can be configured to use the computation capability of the memory chip (e.g., integrated circuit die 105) to perform inference computations of an application, such as the inference computation of an artificial neural network. The inference results can be stored in a portion of the memory cell array 113 for retrieval by an external device via the interface 125 of the integrated circuit device 101.

Optionally, at least a portion of the voltage drivers, the digitizers, the shifters, the adders, and the control logic can be configured in the integrated circuit die 109 for the logic chip.

The memory cells (e.g., memory cells of array 113) can include volatile memory, or non-volatile memory, or both. Examples of non-volatile memory include flash memory, memory units formed based on negative-and (NAND) logic gates, negative-or (NOR) logic gates, phase-change memory (PCM), magnetic memory (MRAM), resistive random-access memory, cross point storage and memory devices. A cross point memory device can use transistor-less memory elements, each of which has a memory cell and a selector that are stacked together as a column. Memory element columns are connected via two layers of wires running in perpendicular directions, where wires of one layer run in one direction in the layer located above the memory element columns, and wires of the other layer are in another direction and in the layer located below the memory element columns. Each memory element can be individually selected at a cross point of one wire on each of the two layers. Cross point memory devices are fast and non-volatile and can be used as a unified memory pool for processing and storage. Further examples of non-volatile memory include read-only memory (ROM), programmable read-only memory (PROM), erasable programmable read-only memory (EPROM) and electronically erasable programmable read-only memory (EEPROM) memory, etc. Examples of volatile memory include dynamic random-access memory (DRAM) and static random-access memory (SRAM).

The integrated circuit die 105 and the integrated circuit die 109 can include circuits to address memory cells in the memory cell array 113, such as a row decoder and a column decoder to convert a physical address into control signals to select a portion of the memory cells for read and write. Thus, an external device can send commands to the interface 125 to write weights into the memory cell array 113 and to read results from the memory cell array 113.

In some implementations, the image processing logic circuit 121 can also send commands to the interface 125 to write images into the memory cell array 113 for processing.

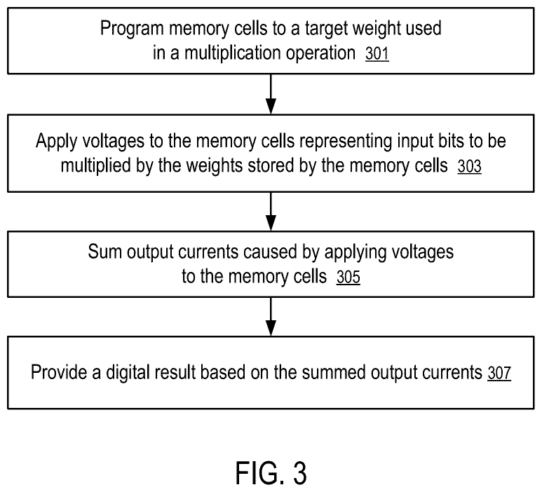

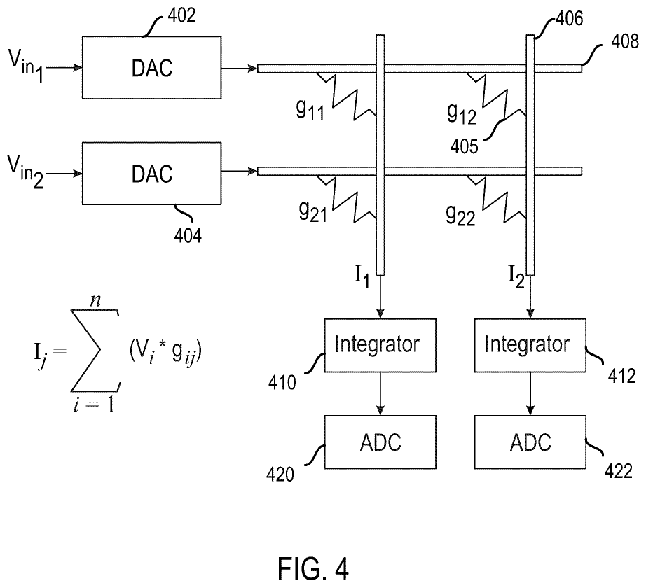

FIG. 3 shows a method of computation in an integrated circuit device based on summing output currents from memory cells according to one embodiment. For example, the method of FIG. 3 can be performed in an integrated circuit device 101 of FIG. 1 using multiplication and accumulation techniques of FIG. 2 or 4.

The method of FIG. 3 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 3 is performed at least in part by one or more processing devices (e.g., a controller 124 of inference logic circuit 123 of FIG. 1, or a local controller (not shown) of integrated circuit die 105).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 301, memory cells (or sets of memory cells such as 4-cell sets storing a bit of a signed weight) are programmed to a target weight for performing multiplication. In one example, memory cells of memory cell array 113 are programmed. In one example, memory cells 207, 206, 208 are programmed to store weights of different bit significance. The weights correspond to a multi-bit weight (e.g., Weight1 of FIG. 6).

At block 303, voltages are applied to the memory cells. The voltages represent input bits to be multiplied by the weights stored by the memory cells. In one example, voltage drivers apply input voltages 205, 215, 225.

At block 305, output currents from the memory cells caused by applying the voltages are summed. In one example, the output currents are collected and summed using line 241 as in FIG. 2.

At block 307, a digital result based on the summed output currents is provided. In one example, the summed output currents are used to generate Result X 237 of FIG. 2.

In one embodiment, some of the memory cells have a first threshold voltage programmed to represent a value of one, and the applied voltage is less than the first threshold voltage.

In one embodiment, the applied voltage is less than the first threshold voltage by at least 0.5 volts.

In one embodiment, the device further comprises an interface (e.g., 125) operable for a host system to write data into the memory cell array and to read data from the memory cell array.

In one embodiment, the memory cells include first and second memory cells; the respective weight stored by the first memory cell is a most significant bit (MSB) of a multi-bit weight; and the respective weight stored by the second memory cell is a least significant bit (LSB) of the multi-bit weight.

In one embodiment, the digitizer is configured in an analog-to-digital converter.

FIG. 4 shows an analog weight-stationary architecture for matrix vector multiplication (MVM) according to one embodiment. Because the computational burden is largely on the MVM operation when executing a neural network, an analog weight-stationary architecture is used that focuses on the MVM operation. The other computations/logic required can generally be implemented in the digital and/or analog space since their impact on performance and energy efficiency is relatively small.

In a weight-stationary architecture, the computation is performed where the weights are stored (e.g., performed in a NAND or NOR flash memory device that stores weights). This removes or reduces the performance bottleneck and power inefficiency of moving the weights out of memory for the computation. The MVM computation is performed in the analog domain. This typically results in some computational error that does not exist in the digital domain.

The weights are stored in storage units 405 (e.g., memory cells) within the memory device (e.g., 101). The input is sent to an electrode 408 of the storage unit, resulting in a multiplication of the input and the weight (conductance of storage unit based on the stored weight) (e.g., weight of g12 multiplied by input Vin₁). Digital-to-analog converters (DAC) 402, 404 convert digital inputs into magnitudes for analog voltages used to drive electrodes 408 (e.g., an access line such as a select gate drain line).

The result is summed to another electrode (e.g., 406) (e.g., a common line 241 of FIG. 2) within the memory array and detected by an ADC 420, 422. For example, integrators 410, 412 accumulate currents I₁, I₂ from memory cells 405 determined by the conductances of the cells and provide the accumulated currents as inputs to ADC 420, 422.

In one embodiment, a memory device performs MVM on weights stored within memory cells of a three-dimensional (3D) array. Weights are stored within the memory cells. The memory cells extend vertically upwards from a semiconductor substrate (not shown). The memory cells are arranged as vertical pillars of cells.

The threshold voltage (VT) of a memory cell is set (programmed) based on the intended weight. When the cell is read with a fixed wordline voltage, the cell will sink some current (based on the cell I-V characteristics) as a function of the weight stored within the cell.

In one embodiment, a three-dimensional memory cell array has a NOR configuration with memory cells connected in parallel. The memory cell array is an example of memory cell array 113 of FIG. 1.

The array includes memory cells arranged in various vertical pillars with each cell in a pillar connected to a vertical local digit line. The array is located above a semiconductor substrate (not shown). The memory cells are also arranged as horizontal tiers. The tiers are stacked vertically.

Each of the cells is connected to a wordline that extends horizontally. Each memory cell is biased by applying a voltage to one of the wordlines and one of the local digit lines to which the cell is connected. When performing multiplication, memory cells in one or more of the tiers are selected by applying a voltage to wordlines.

Each local digit line of a pillar is connected to a global digit line using a select transistor. When performing multiplication, output currents from the selected memory cells of a tier(s) are accumulated on global digit lines. In some embodiments of a resistive array, multiple tiers can be selected at the same time for computation.

In one embodiment, each of the memory cells is programmed to store a weight bit for performing multiplication. For the selected tier of memory cells that will be used for multiplication, a voltage is applied on the wordline of each cell so that each memory cell can contribute an extent of output current that is dependent on the programming state of the memory cell.

Voltages are applied to the memory cells when performing multiplication, such as discussed above. The applied voltages represent input bits to be multiplied by the weight bits stored by the memory cells. The voltages are applied to gates of select transistors using select lines (e.g., SL−, SL+). Output currents from the memory cells are then summed on global digit lines and a digital result provided, such as discussed above.

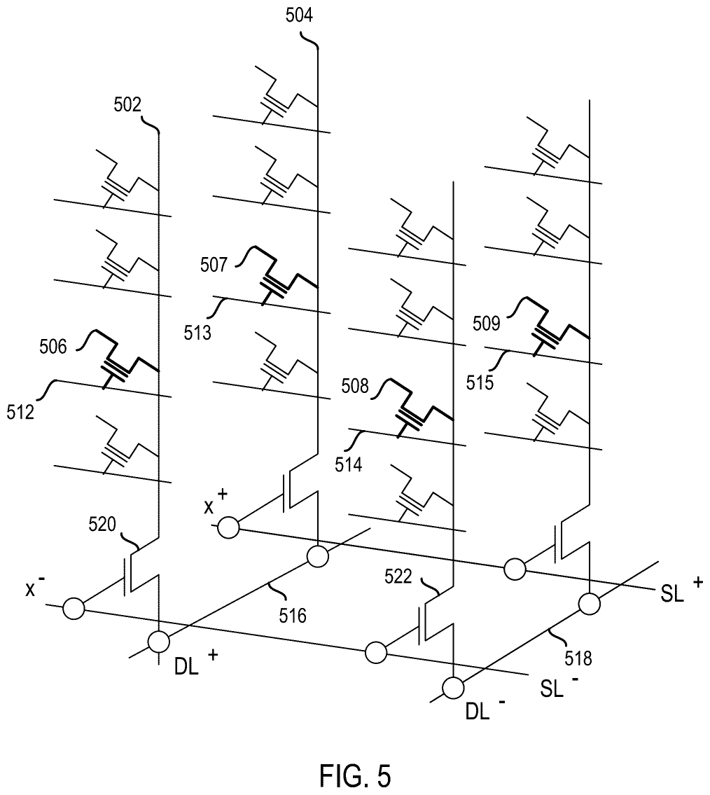

FIG. 5 shows a three-dimensional memory cell array having floating gate memory cells in a NOR configuration according to one embodiment. The memory cells are connected in parallel. The memory cell array illustrated in FIG. 5 is an example of memory cell array 113.

Similarly as discussed above, the memory cells can be arranged in horizontal tiers. One or more of the tiers is selected for performing multiplication. For example, memory cells 506, 507, 508, 509 are selected by applying a gate voltage to each cell. The voltage is applied using wordlines 512, 513, 514, 515.

In one embodiment, wordlines 512 and 514 are connected as a single line. Wordlines 513 and 515 are also connected as a single line.

The memory cells of the array are arranged in pillars each having a vertical local digit line 502, 504. Each local digit line is coupled to a global digit line 516, 518 by select transistors 520, 522.

In one embodiment, each of the memory cells is programmed to store a weight bit for performing multiplication. For the selected tier of memory cells that will be used for multiplication, a voltage is applied on the wordline so that each memory cell can contribute an extent of output current that is dependent on the programming state of the memory cell.

Voltages are applied to the memory cells when performing multiplication, such as discussed above. The applied voltages represent input bits to be multiplied by the weight bits stored by the memory cells. The voltages are applied to gates of select transistors 520, 522 using select lines (SL). Output currents from the memory cells are then summed on global digit lines 516, 518, and a digital result provided, such as discussed above.

Various memory cell implementations can be used for performing signed multiplication. In one embodiment, the signed multiplication is performed in a so-called four-quadrant system, in which each of an input and a weight to be multiplied can have a positive or negative sign. For example, some neural network models make use of matrix vector multiplication in which the weights of the model are signed. In one example, resistive random-access memory (RRAM) cells are used. In one example, NAND or NOR flash memory cells are used.

In one embodiment, matrix vector multiplication is performed using stored weights. Input signals are multiplied by the weights to provide a result. In one example, the weights are determined by training a neural network model. The model uses both positive and negative values for the weights. In one example, the weights are stored in memory cells of memory cell array 113 of FIG. 1. In one example, the model is trained using image data, and the trained model provides inference results based on inputs from an image sensor.

In one embodiment, a multiplier accumulator unit uses signed multiplication. Weights may be represented by multi-bit values (e.g., 8-64 bits). An extra bit is used to represent the sign of a weight value. For example, a system may use 8 bit signed weights, where values of the weights are represented by seven bits, and the eighth bit is used to represent the sign. An extra bit can be used in a similar manner for signed inputs.

In one embodiment, a signed 1-bit number (e.g., an input and/or weight) has one of three possible values: −1, 0, 1. For example, a signed weight can be represented by a 2-bit number, where a 2-bit value of 01 represents a signed 1-bit value of −1; a 2-bit value of 00 represents a signed 1-bit value of 0; and a 2-bit value of 10 represents a signed 1-bit value of +1. The 2-bit value of 11 is not used. In other examples, the various combinations of the 2 bits can represent different signed values, as may be desired for a given implementation.

In one example, a controller that controls multiplications manages the two bit values by keeping track of the meaning represented by each bit (e.g., sign or magnitude). In one example, the controller is part of inference logic circuit 123 of FIG. 1.

1-bit by 1-bit multiplications of the two-bit numbers representing the signed 1-bit input and the signed 1-bit weight can be configured to produce a result for signed 1-bit to 1-bit multiplication. In one example, the result has been determined in response to a request from a host system over interface 125 of FIG. 1. In one example, the signed inputs used to produce the result are based on data collected by image sensing pixel array 111 of FIG. 1.

In one embodiment, a two-cell implementation is used for signed 1-bit to 1-bit multiplication. Two memory cells of a set are used to store the two bits of the signed 1-bit weight in the two-bit representation.

Two input lines are used to apply the two bits of the signed 1-bit input (two-bit representation) (sometimes referred to herein as a “positive version”) at a first time instance (e.g., a first clock cycle, T0), and then a negative version of the input at a second time instance (e.g., a second clock cycle, T1).

In one embodiment, a four-cell implementation is used for signed 1-bit to 1-bit multiplication. Four memory cells of a set are used to store the two bits of the signed 1-bit weight in the two-bit representation (sometimes referred to herein as a “positive version”) and also in a negative version of the two-bit representation. Two input lines are used to apply the two bits of the signed 1-bit input (two-bit representation).

In one example, the input lines provide voltages to a memory cell set. The set has four memory cells. In one example, the input lines can be wordlines, bitlines, or select gate lines (SL or SGD), depending on type of memory cell and the particular set configuration (e.g., memory cells arranged in series as for NAND flash versus memory cells arranged in parallel as for RRAM or NOR).

The first pair of memory cells is multiplied by the signed input. The output currents are summed on a first line. The second pair of memory cells is also multiplied by the signed input. The output currents are summed on a second line.

The bit result (e.g., 0 or 1) for the first line provides the first bit of the signed 1-bit to 1-bit multiplication (two-bit representation). The bit result (e.g., 0 or 1) for the second line provides the second bit of the signed 1-bit to 1-bit multiplication (two-bit representation). In one example, these first and second bit results provide a 1-bit signed result.

In one example, an image is provided as an input to a neural network. The neural network includes convolution layers. The size of each layer varies. For example, each layer has a different number of features and neurons. For example, one layer uses a smaller number of filters than another layer. The neural network provides a final result. In one example, the final result is a classification of an object represented by the image.

When performing computations, matrix vector multiplication operations are mapped to tiles in a memory cell array (e.g., 113). For example, this mapping involves identifying portions of the memory cell array that are to be used during the computation for a particular layer. This mapping typically varies as computations progress from one layer to another.

In one example, the image is data obtained from image sensing pixel array 111. In one example, weights for the neural network have been programmed into memory cells of tiles 141, 142. In one example, a different memory array configuration is used for each layer as computations progress from one layer to another.

In one example, tiles of a memory device are configured to be partially filled for performing a multiplication or other operation for a neural network. The tiles are in a memory cell array (e.g., 113). In one example, the array includes about 1,500 NAND or NOR tiles. The tiles are filled (programmed) with weights for neurons to be used (e.g., used for at least one layer). The particular weights that are valid for a given MVM computation will vary, as discussed above.

In one embodiment, a NAND or NOR memory device has a register that is exposed to a host interface. The host can set registers to configure the NAND or NOR device (e.g., a parameter can be defined by the host). For example, the NAND or NOR device can provide fixed options to the host of certain predefined neuron sizes. The host can select one of the predefined neuron sizes that is closest to the size of the current computation. The NAND or NOR device uses logic circuitry to set the configuration based on the definition by the host of the predefined neuron size.

In one embodiment, the host or local controller communicates the neuron size in a register. In one embodiment, the NAND or NOR device selects one of the predefined neuron sizes above based on the neuron size stored in the register.

In one embodiment, a memory device uses a memory cell array organized as sets of memory cells. In one example, resistive random-access memory (RRAM) cells are used. In one example, NAND or NOR flash memory cells are used.

Each set is programmable to store a multi-bit signed weight. After being programmed, voltage drivers apply voltages to the memory cells in each set. The voltages represent multi-bit signed inputs to be multiplied by the multi-bit signed weights.

One or more common lines are coupled to each set. The lines receive one or more output currents from the memory cells in each set (e.g., similarly as discussed above for sets of two or four cells). Each common line accumulates the currents to sum the output currents from the sets.

In one example, the line(s) are bitline(s) extending vertically above a semiconductor substrate. As an example, 512 memory cell sets are coupled to the line(s). Inputs are provided using 512 pairs of select lines (e.g., SL+, SL−), with one pair used per set. The output currents from each of the 512 sets are collected on the line(s), and then one or more total current magnitudes are digitized to provide first and second digital values.

In one example, the memory device includes one or more digitizers. The digitizer(s) provide signed results (e.g., as described above) based on summing the output currents from each of the 512 sets on first and second digit lines.

A first digital value (e.g., an integer) representing the current on the first digit line is determined as the multiple of a predetermined current (e.g., as described above) representing 1. A second digital value representing the current on the second digit line is determined as the multiple of the predetermined current. The first and second digital values are, for example, outputs from a digitizer(s).

In one embodiment, a memory device includes a memory cell array having sets of NOR flash memory cells (e.g., using memory cell array 113). Each set is programmable to store a multi-bit signed weight. Voltage drivers apply voltages to each set. The voltages correspond to a multi-bit signed input, which is multiplied by the multi-bit signed weight for each set. Two common lines are coupled to each set. Each common line sums a respective output current from each set. A digitizer on each common line provides signed results based on summing the output currents from the sets. Each signed result corresponds to a bit significance of the input and a bit significance of the weight, for example as described above. The signed results are added together taking respective bit significance into consideration to provide first and second digital values that represent a signed accumulation result from the multi-bit to multi-bit multiplication.

In one embodiment, a signed input is applied to a set of memory cells on two wires (e.g., two select lines), each wire carrying a signal. Whether the input is positive or negative depends on where the magnitude of the signal is provided. In other words, the sign depends on which wire carries the signal. The other wire carries a signal of constant value (e.g., a constant voltage corresponding to zero).

Every signed input applied to the set is treated as having a positive magnitude. One of the two wires is always biased as a zero (biased as a constant signal more generally). The other wire carries the magnitude of the input pattern.

In one embodiment, a multi-bit input is represented as a serial or time-sliced input provided on the two wires. For example, the input pattern is a number of bits (e.g., 1101011) for which corresponding voltages are serially applied to the wire, one bit per time slice. In one example, input bits are applied serially one at a time.

In one embodiment, the contribution of output current to common lines from each one of the memory cells varies corresponding to the MSB, MID, or LSB significance of the bit stored by the memory cell (e.g., stored for 3 bits in a group of 3 memory cells above). The contribution for MSB significance (e.g., 100 nA) is two times greater than for MID significance (e.g., 50 nA). The contribution for MID significance is two times greater than for LSB significance (e.g., 25 nA).

When the output current contribution takes bit significance into consideration, then left shifting is not required when adding the signed results (e.g., first, second, third, and fourth signed results) to obtain a signed accumulation result. Instead, the signed results can be added directly without left shifting.

In one embodiment, a memory device performs analog summation of 1-bit result currents having different bit significance implemented via different bias levels. A memory cell (e.g., a RRAM cell or NOR flash memory cell) can be programmed to have exponentially increased (e.g., increasing by powers of two) current for different bias levels.

In one embodiment, a memory cell can be programmed to have a threshold with exponentially increased current for higher bias/applied voltage. A first voltage can be applied to the memory cell to allow a predetermined amount of current (indicated as 1×) to go through to represent a bit value of 1 for the least significant bit.

To represent a bit value of 1 for the second least significant bit, a second voltage can be applied to the memory cell to allow twice (indicated as 2×) the predetermined amount of current to go through, which is equal to the predetermined amount of current multiplied by the bit significance of the second least significant bit.

The memory cell can be similarly biased to have a higher amount of current equal to the predetermined amount of current multiplied by the bit significance of the bit when the bit value is 1.

When different voltages are applied to memory cells each representing one bit in a number such that the respective bit significance of each cell is built into the output currents as described above, the multiplication results involving the memory cells can be summed via connecting them to a line without having to convert the currents for the bits separately for summation.

For example, a 3-bit-resolution weight can be implemented using three memory cells. Each memory cell stores 1-bit of the 3-bit weight. Each memory cell is biased at a separate voltage level such that if it is programmed at a state representing 1, the current going through the cell is a base unit times the bit significance of the cell. For example, the current going through the cell storing the least significant bit (LSB) is a base unit of 25 nA, the cell storing the middle bit (MID) 2 times (2×) the base unit (50 nA), and the most significant bit (MSB) 4 times (4×) the base unit (100 nA).

In one embodiment, a solid-state drive (SSD) or other storage device uses a memory cell array having memory cells. In one example, resistive random-access memory (RRAM) cells are used. In one example, NAND or NOR flash memory cells are used.

In one embodiment, each memory cell is programmable to store one bit of a multi-bit weight. After being programmed, voltage drivers apply different voltages to bias the memory cells for use in performing multiplication. Inputs to be multiplied by the multi-bit weights can be represented by a respective input pattern applied to select gates of select transistors coupled to the memory cells (e.g., as described above), or by varying the different voltages between a fixed voltage state representing an input bit of 1 and a zero state representing an input bit of 0.

One or more common lines are coupled to the memory cells. The lines receive one or more output currents from the memory cells (e.g., as described above). Each common line (e.g., digit line or bitline) is used to accumulate the currents to sum the output currents.

In one embodiment, three memory cells store values representing three bits of a stored weight. One bit is for an MSB, one bit is for a bit of middle significance (sometimes indicated as “MID” herein), and one bit is for an LSB. This provides a multi-bit representation for the stored weight.

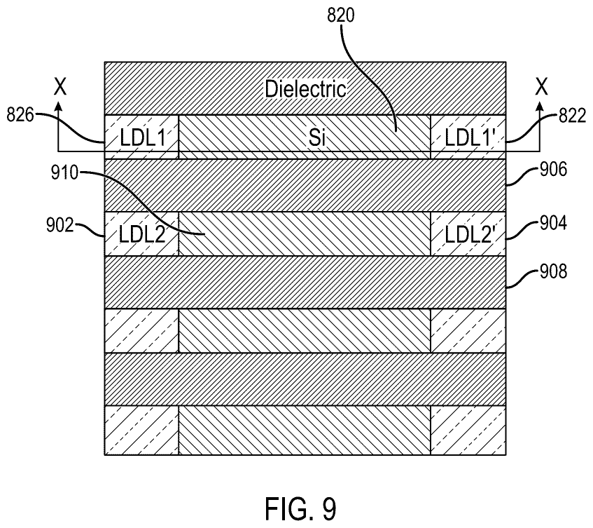

FIG. 6 shows an architecture having resistive random access memory (RRAM) or NOR memory cells arranged in a memory cell array 602 in a parallel configuration for performing multiplication (e.g., MVM) according to one embodiment. For example, memory cells 630, 631, 632 store bits of respective significance for a multi-bit weight (indicated as Weight1). A simple 3-bit weight is illustrated, but a larger number of bits can be stored for each weight. When performing multiplication, each of memory cells 630, 631, 632 can be accessed in parallel. In one example, memory cell array 602 includes memory cells arranged as illustrated in FIG. 9.

Each memory cell provides an output current that corresponds to a significance of a bit stored by the memory cell. Memory cells 630, 631, 632 are connected to a common line 610 for accumulating output currents. In one example, line 610 is a bitline.

Different voltages V1, V2, V3 are applied to memory cells 630, 631, 632 using wordlines 620, 621, 622. Voltages are selected so that the output currents vary by a power of two based on bit significance, for example as described above.

In one embodiment, an input signal I1 is applied to the gate of select transistor 640. Select transistor 640 is coupled to common line 610. An output of select transistor 640 provides a sum of the output currents. In one embodiment, when the input signal is applied to the gate of select transistor 640, the different voltages V1, V2, V3 are held at a constant voltage level.

In an alternative embodiment, an input pattern for multiplication by Weight1 can be applied to wordlines 620, 621, 622 by varying the different voltages V1, V2, V3 between fixed voltages and zero voltages similarly as described above to represent input bits of 1 or 0, respectively.

Memory cell array 602 is formed above semiconductor substrate 604. In one embodiment, memory cell array 602 and semiconductor substrate 604 are located on different chips or wafers prior to being assembled (e.g., being joined by bonding).

Similarly, as described above for Weight1, multi-bit weights Weight2 and Weight3 can be stored in other memory cells of memory cell array 602, and output currents accumulated on common lines 611, 612, as illustrated. These other memory cells can be accessed using wordlines 620, 621, 622. Common lines 611, 612 are coupled to select transistors 641, 642, which each provide a sum of output currents as an output. Input patterns I2, I3 can be applied to gates of the select transistors. Additional weights can be stored in memory cell array 602.

Output currents from common lines 610, 611, 612 are accumulated by accumulation circuitry 650. In one embodiment, accumulation circuitry 650 is formed in semiconductor substrate 604 (e.g., formed at a top surface).

In one embodiment, voltage drivers 606 and biasing circuitry 605 are formed in semiconductor substrate 604. Logic circuitry (not shown) formed in semiconductor substrate 604 is used to implement controller 603. Controller 603 controls voltage drivers 606 and biasing circuitry 605.

In one embodiment, voltage drivers 606 provide the different voltages V1, V2, V3. Biasing circuitry 605 applies inputs I1, I2, I3.

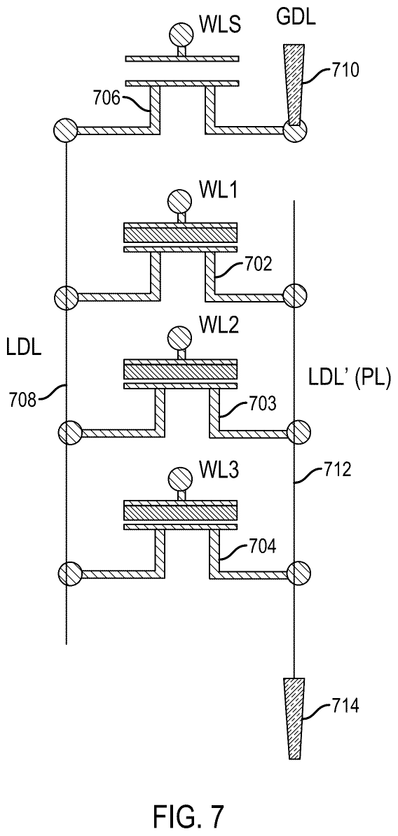

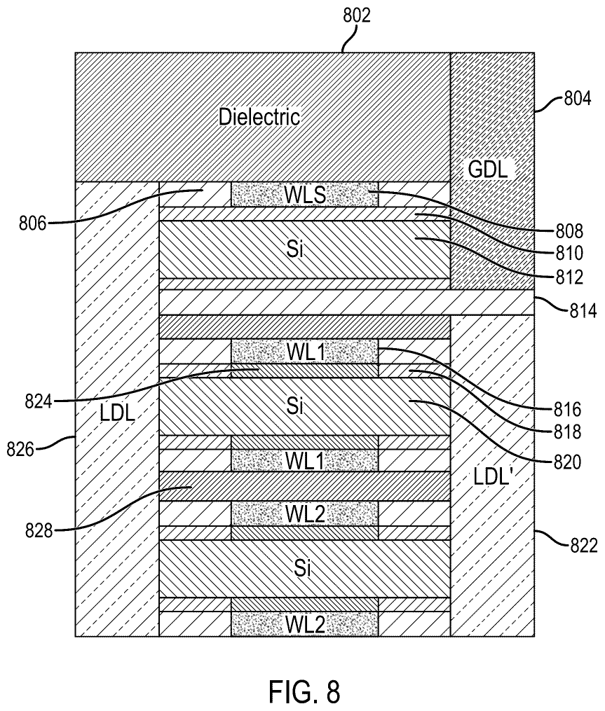

FIG. 7 shows memory cells 702, 703, 704 arranged in an electrically parallel configuration with current terminals connected to a common global digit line (GDL) 710 by a select transistor 706 according to one embodiment. Memory cells 702, 703, 704 are stacked vertically above a substrate (not shown) (see, e.g., FIG. 8 as a structural example). Each memory cell is biased by a wordline (e.g., WL1, WL2). In one example, memory cells 702, 703, 704 are flash memory cells configured in memory cell array 113. In some embodiments, a current terminal of select transistor 706 electrically connects to global digit line 710 using a via.

Local digit line (LDL) 708 electrically connects one current terminal of each memory cell to global digit line 710 using select transistor 706. Select transistor 706 is controlled (e.g., switched on or off) by a select line (e.g., WLS).

Another current terminal of each memory cell is connected to local digit line (LDL′) 712. In some embodiments, each memory cell is connected to a different local digit line 712. In other embodiments, each memory cell is connected to a common local digit line 712 (sometimes referred to as a common plate (PL)). Local digit line 712 connects to a biasing circuit via interconnect 714 (e.g., a via).

In some embodiments, several of LDL′ (PL) may be shorted together. In some embodiments, the connection to LDL′ can run along the bottom of the memory array similarly to how GDL runs along the top of the memory array.

In one embodiment, logic circuitry (not shown) is located beneath the memory cells (e.g., in a logic chiplet). The logic circuitry drives voltages on global digit line 710, local digit line 712, wordlines WL1, WL2, WL3, and select line WLS.

Output currents from one or more selected memory cells are accumulated by local digit line 708. In one embodiment, memory cells 702, 703, 704 are organized in a vertical pillar. The output currents from memory cells of multiple such pillars (not shown) are accumulated by global digital line 710, which is connected to local digital lines (not shown) of each pillar. Global digit line 710 is also connected to accumulation circuitry (not shown).

In one embodiment, each memory cell represents a bit of equal bit significance (e.g., all bits are of a least significance (LSB)). In one embodiment, two or more memory cells can be used together to represent a single bit having a greater significance. For example, the wordlines WL2, WL3 of memory cells 703, 704 can be electrically shorted together so that the output currents from memory cell 703, 704 correspond to multiplication using a single bit of most significance (MSB).

In one embodiment, an input pattern to be multiplied by weights stored in memory cells 702, 703, and/or 704 is applied by varying the voltage on the select line WLS. In one embodiment, an input pattern to be multiplied by weights stored in memory cells 702, 703, and/or 704 is applied by varying the voltage on the wordlines of the selected memory cells. In one embodiment, the wordline voltage is changed in the time domain (e.g., a memory device implements time-sliced unsigned multi-bit to multi-bit multiplication).

In one embodiment, each memory cell stores a single bit (binary single-level cell (SLC)). In one embodiment, each memory cell stores multiple bits (e.g., MLC, TLC).

FIG. 8 is a cross-sectional view taken as illustrated in FIG. 9 (indicated by “XX”) and shows a memory device having NOR flash memory cells (e.g., 50-200 transistors) stacked in a pillar vertically above a semiconductor substrate (not shown) according to one embodiment.

Each memory cell is implemented by one of multiple transistors stacked vertically in pillars above the substrate. Each transistor has a semiconductor layer 820 (e.g., silicon, polysilicon, oxide semiconductor) to provide a channel. The channel extends in a horizontal direction (e.g., left to right in FIG. 8) relative to the substrate. Each semiconductor layer 820 also provides a source and drain for each transistor.

Each transistor also has a gate stack layer 818 (e.g., an oxide-nitride-oxide (ONO) stack, ANO, ONOA, etc.) that wraps around the outer circumference of the semiconductor layer 820. A memory storage element 824 for each transistor is provided by the portion of gate stack layer 818 that is aligned with the respective portion of wordline 816 (e.g., WL1, WL2) for the transistor. The wordlines run in a direction in and out of the paper surface of FIG. 8. In some embodiments, the wordline (WL) metal may only be on two sides (top and bottom) and not on a sidewall. In one embodiment, the WL has a staircase, and contacts are located at the end of the WL. For example, the wordlines (WL's) are contacted at the edge of the memory array with a staircase of contacts.

In one embodiment, peripheral CMOS circuitry can be located either under the array or over the array.

In one embodiment, the vertical spacing between the memory cells may vary. In one embodiment, the WL for some of the vertical cells may be shorted together and isolation eliminated, effectively connecting the memory cells in parallel with improved density.

The wordlines are used to apply gate voltages to the transistors. A portion of each wordline wraps around the outer circumference of the gate layer of each transistor. Isolation layers 828 (e.g., oxide) electrically separate the wordlines of each transistor in a pillar.

Local digit line 826 (e.g., LDL1) is connected to a first terminal of each transistor. Local digit line 822 (e.g., LDL1′) is connected to a second terminal of each transistor. Local digit lines 826 and 822 each extend vertically above the substrate.

A select transistor is located above the memory cells of the pillar, as illustrated. Semiconductor layer 812 (e.g., silicon) provides a channel for the select transistor. The select transistor electrically connects local digit line 826 to global digit line 804. The select transistor is controlled by select line 808 (WLS). Insulating layer 810 electrically separates select line 808 and semiconductor layer 812. In one embodiment, global digit line (GDL) 804 extends in a horizontal direction relative to the substrate.

Dielectric layer 802 (e.g., oxide) and isolation layers 806, 814 (e.g., oxide or nitride) provide electrical isolation for various components as illustrated.

Global digit line 804 is electrically connected to accumulation circuitry (not shown) that accumulates, using global digit line 804 and other global digit lines (not shown), output currents from selected ones of the transistors when performing a multiplication operation.

FIG. 9 shows a top view of the memory device of FIG. 8 having multiple pillars of memory cells electrically isolated by one or more dielectric materials 906, 908 (e.g., oxide or nitride) according to one embodiment. For example, local digit line 826 is isolated from local digit line 902 by dielectric material 906. Local digit line 822 is isolated from local digit line 904 by dielectric material 906.

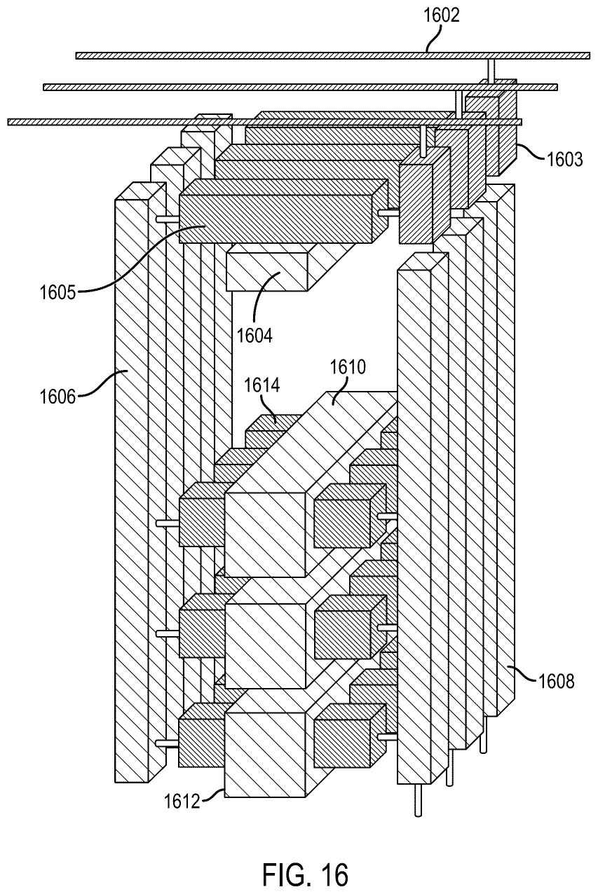

Semiconductor layer 820 corresponds to a first memory cell. Semiconductor layer 910 corresponds to a second memory cell. The first and second memory cells are electrically isolated by dielectric material 906. Each memory cell has its gate controlled by a common wordline (not shown). In one example, such a common wordline controls 300-1,000 memory cells. A portion of the wordline wraps around the gate layer of the transistor for each memory cell (see, e.g., wordline 1610 in FIG. 16).

Each memory cell has its current terminals connected to different local digit lines. For example, semiconductor layer 910 provides a channel that is electrically connected to local digital lines 902, 904. This is electrically isolated from semiconductor layer 820, which provides a channel electrically connected to different local digital lines 822, 826.

In one embodiment, each storage transistor uses silicon to provide a horizontal channel. Each storage transistor is bit level addressable due to being arranged in a NOR configuration. Each storage transistor has a direct access line for its source and drain. The storage element is in the gate stack of each transistor. In one example, a gate stack is used in layer 818 to provide an ONO or TANOS cell. In one example, a charge trap stack is used. In operation, trapped charge in the storage element modulates the threshold voltage of the transistor, which changes its read current when doing multiplication.

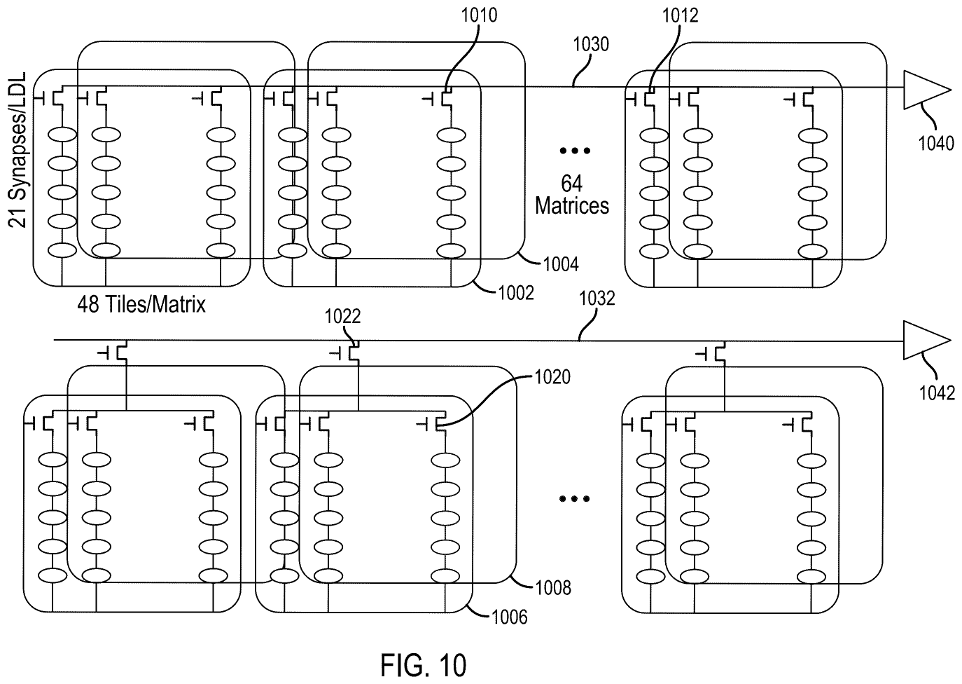

FIG. 10 shows exemplary matrices of memory cells with each matrix having multiple tiles 1002, 1004, and each tile having multiple pillars of memory cells according to one embodiment. In one example, each pillar has memory cells configured as illustrated in FIG. 8.

The memory cells of each pillar are connected to global digit line 1030 by select transistors 1010, 1012. Global digit line 1030 is connected to conversion circuitry 1040 (e.g., an analog to digital converter). Output currents from the memory cells are accumulated on global digit line 1030. Conversion circuitry 1040 provides a digital result based on a magnitude of the total accumulated current.

In one example, each matrix has 48 tiles. Each pillar is associated with a local digit line (e.g., 826). There are 21 synapses for each local digit line.

For example, three vertical memory cells are used per synapse for three-bit resolution. Each of the memory cells is on a different horizontal tier of the memory array.

In an alternative embodiment, decoding by the selected transistors can be implemented using two tiers of decoding. A first tier corresponds to select transistor 1022, and a second tier corresponds to select transistor 1020. Output currents from memory cells of tiles 1006, 1008 are accumulated on global digit lines (e.g., 1032). Digital results are generated by conversion circuitry (e.g., 1042) connected to the global digit lines. Two tier decoding can reduce capacitance load on the global digit line and/or local digit line (e.g., by isolating the capacitance of unused lower level select transistors).

In one example, controller 124 uses select transistors 1010, 1012, and/or 1022, 1020 to configure a memory array for multiplication by turning on or off particular tiles of the memory array. The number of tiles used for a given multiplication will vary depending on the particular neural network being supported (e.g., depend on a size of the layer of the neural network currently being used).

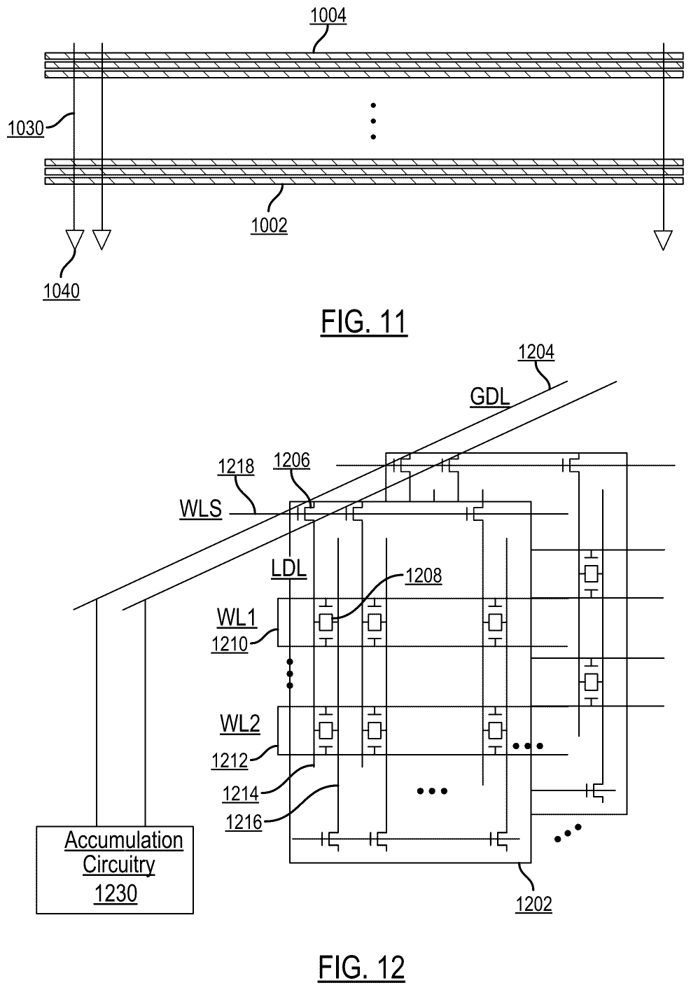

FIG. 11 shows a top view of tiles 1002, 1004 in an exemplary matrix of FIG. 10 according to one embodiment. Tiles 1002, 1004 are arranged, for example as illustrated, in parallel as thin rectangular slivers. Global digit lines (e.g., 1030) run in a direction perpendicular to the parallel arrangement of tile slivers. Each global digit line accumulates output currents from selected memory cells of tiles 1002, 1004.

FIG. 12 shows a memory device having global digit lines 1204 that connect memory cells of different tiles 1202 in a memory cell array to accumulation circuitry 1230 according to one embodiment. Accumulation circuitry 1230 uses output currents accumulated by global digit lines 1204 as input(s) and generates a digital output(s) as a result for a multiplication operation.

Global digit lines 1204 are connected to local digit lines 1214 by select transistors 1206. Select transistors 1206 are controlled by a voltage WLS applied to select lines 1218.

Local digit lines 1214 connect to a first current terminal of each memory cell 1208. Local digit lines 1216 connect to a second current terminal of each memory cell 1208. In one example, local digit lines 1216 are connected to a common plate.

Bias is applied to each memory cell 1208 to vary output currents by using wordlines 1210, 1212. Wordlines 1210, 1212 run in the same direction as select lines 1218. Wordline 1210 is used to select a first tier of the memory array. Wordline 1212 is used to select a second tier of the memory array.

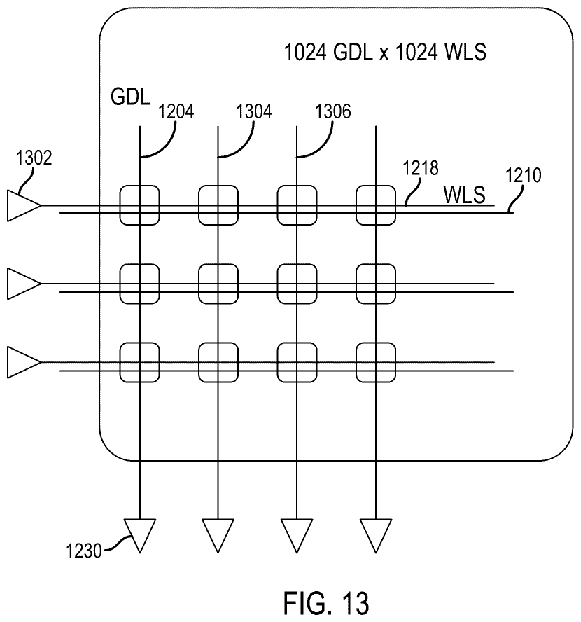

FIG. 13 shows a top view of the memory device of FIG. 12 according to one embodiment. Global digit lines 1204 run perpendicular to select lines 1218. Wordlines 1210 run parallel to select lines 1218. Drivers 1302 (e.g., voltage drivers 115) apply voltages to select lines 1218 and/or wordlines 1210.

Memory cells are configured in vertical pillars 1304, 1306. In one example, each pillar 1304, 1306 has a structure similar to the memory cell structure illustrated in FIG. 8.

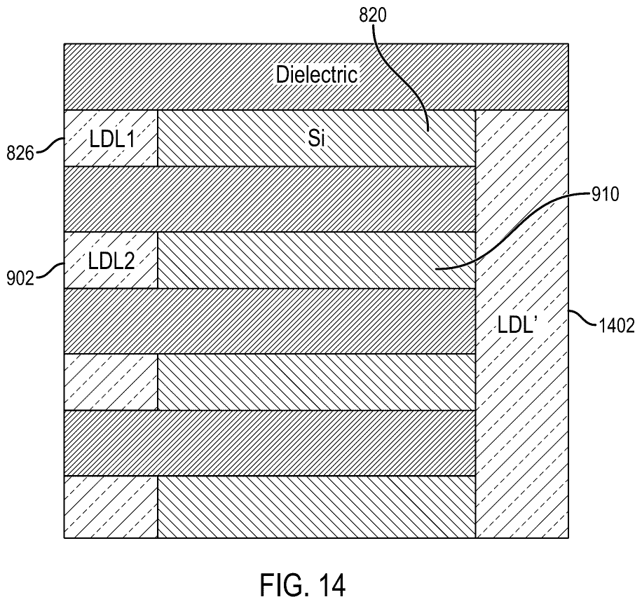

FIG. 14 is top view of a memory device having a structure similar to FIG. 9 except that each of the memory cells in each pillar has one of its two current terminals connected to a common local digit line 1402 (LDL′) according to one embodiment. In one example, common local digit line 1402 is a common plate. Use of the common plate requires use of a batch erase for the memory cells.

In an alternative embodiment, only a portion of the memory cells are shorted to a common plate. Other memory cells can have individual local digit lines 822.

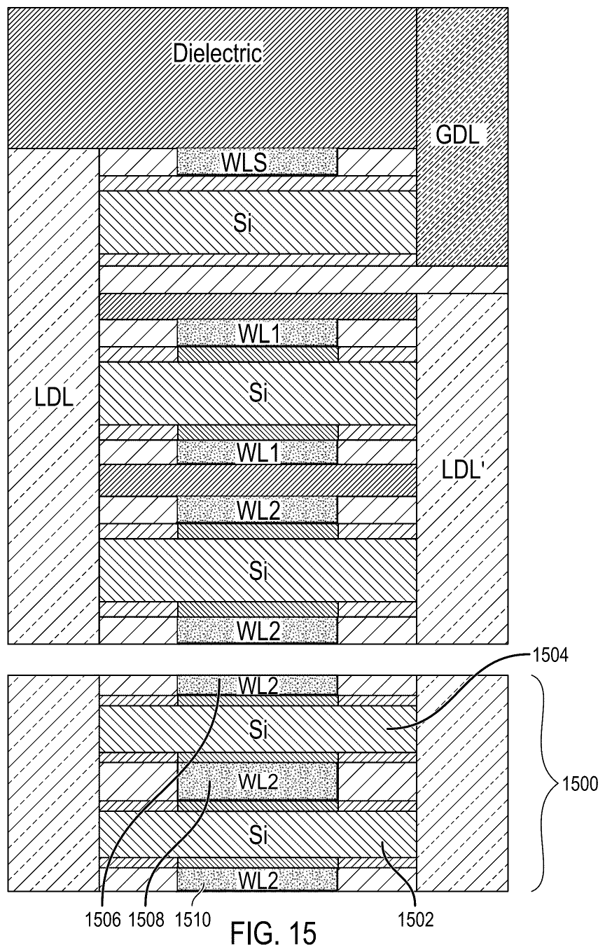

FIG. 15 is a cross-sectional view of a memory device having a structure similar to FIG. 8 except that a portion of memory cells in a pillar have their wordlines electrically shorted together so the memory cells switch on and off as a unit according to one embodiment. For example, silicon layers 1502, 1504 provide channels for two memory cells located vertically relative to each other in two different tiers 1500. Wordline portions 1506, 1508, 1510 are electrically shorted together. Thus, the wordline signal inputs are the same to each memory cell. Also, each memory cell stores the same weight value.

Dielectric isolation is not needed between wordline portions that are electrically shorted in this manner. This reduces the size requirement of the structure. The two memory cells together represent, for example, a most significant bit (MSB), and are switched on or off together.

FIGS. 16-18 show exemplary structures (using a simplified block form merely for purposes of illustration) for configuring local digit lines and memory cells of a memory device according to various embodiments. The simplified blocks in these figures are not drawn to scale and merely illustrate three-dimensional spatial relationships.

FIG. 16 shows local digit lines 1606 that connect a current terminal of each memory cell to global digit lines 1602 using select transistors 1605 and vias (or other interconnect) 1603. Another current terminal of each memory cell is connected to local digit lines 1608 (or a common plate). Select transistors 1605 are controlled by select line 1604.

Each memory cell is controlled or switched by a wordline 1610, 1612. Wordline 1610 controls memory cells in a first tier. Wordline 1612 controls memory cells in a different lower tier. Each wordline wraps around an outer circumference of a gate layer/semiconductor layer 1614.

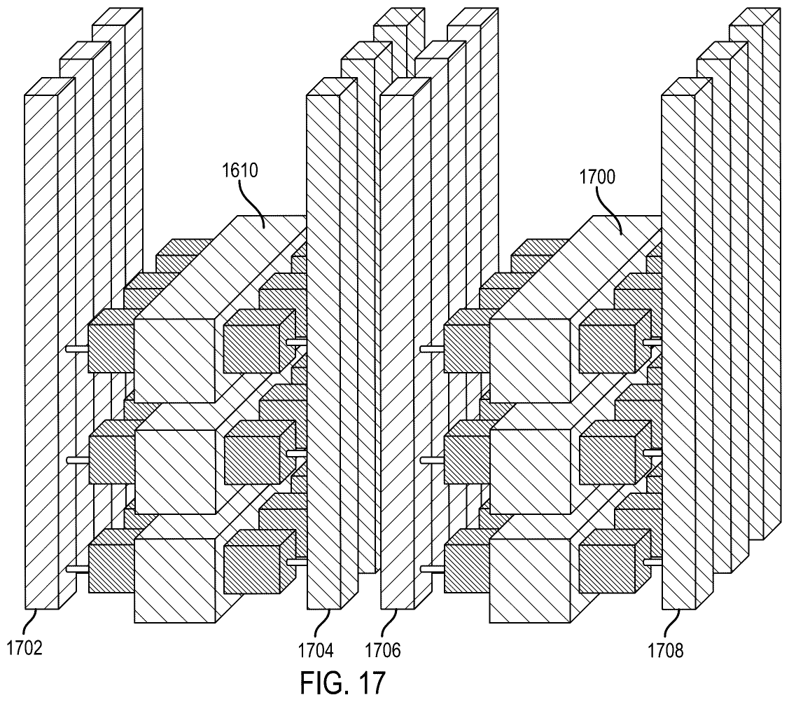

FIG. 17 shows a first pillar of memory cells controlled using wordlines 1610, and a second pillar of memory cells controlled using wordlines 1700. The first pillar uses local digit lines 1702, 1704. The second pillar uses different local digit lines 1706, 1708.

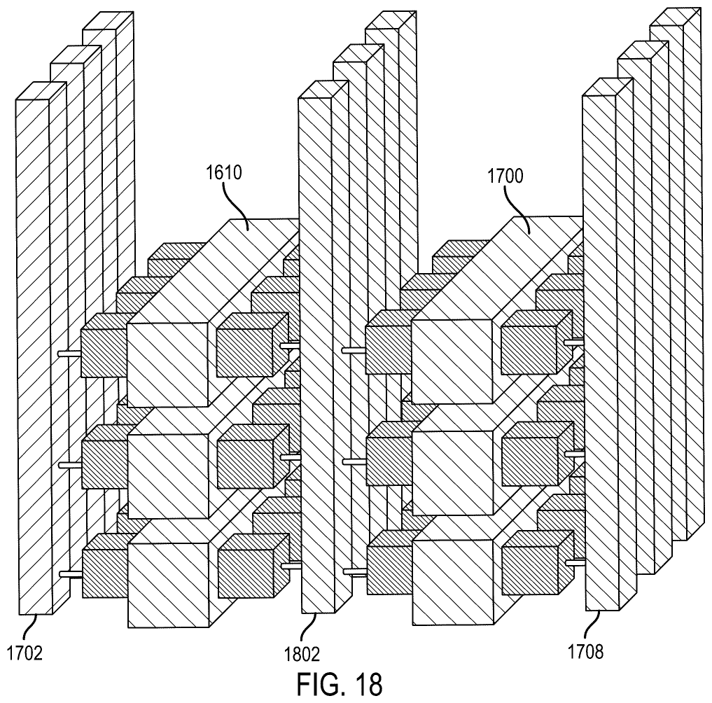

FIG. 18 shows a first pillar of memory cells controlled using wordlines 1610, and a second pillar of memory cells controlled using wordlines 1700. The first pillar uses local digit lines 1702, 1802. The memory cells of the second pillar share local digit lines 1802 for one current terminal of each cell, but use different local digit lines 1708 for the other current terminal of each cell. In this embodiment, it should be noted that the respective gate stack layer for each device is isolated from one device to the next device, but each wordline 1610, 1700 is continuous across the devices.

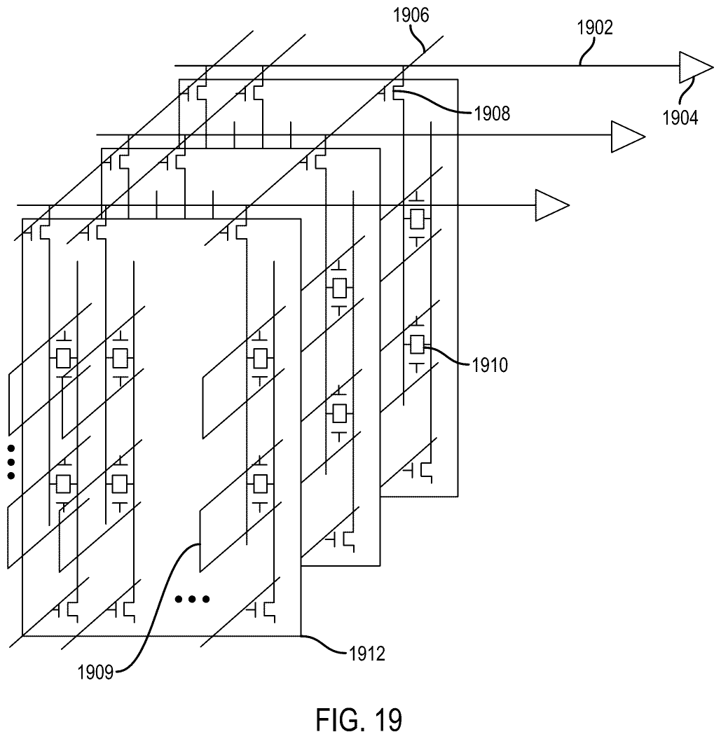

FIG. 19 shows global digit lines 1902 that sum output currents from selected memory cells of tiles 1912 in a memory array according to one embodiment. The memory cells are selected by applying voltages to select lines 1906 and/or wordlines 1909. Accumulators 1904 generate a digital output based on the summed currents. Global digit lines 1902 are connected to local digit lines of the memory cells 1910 in each pillar by select transistors 1908.

In one embodiment (referred to herein as “Case1”), select lines are used to encode an input pattern. Wordlines are used to select a specific tier. The select lines and global digit lines create a cross-point array for any one tier (or groups of tiers if needed for synapse resolution). The tiers are statically selected. The physical array is roughly square in one example. Accumulator 1904 sums current from each pillar of the same tier.

In one embodiment (referred to herein as “Case2”), select lines are used to select a subset of the memory array. Wordlines are used to encode an input pattern. The input pattern is applied at the wordlines. In this case, the tiers may be selected/deselected dynamically to map to the input pattern. The select lines define the size of the physical memory array. For example, the memory array is more compact for the same size electrical array.

Accumulator 1904 sums current from multiple pillars and multiple tiers. Multiple arrays may be supported by the same set of accumulators (e.g., 1904).

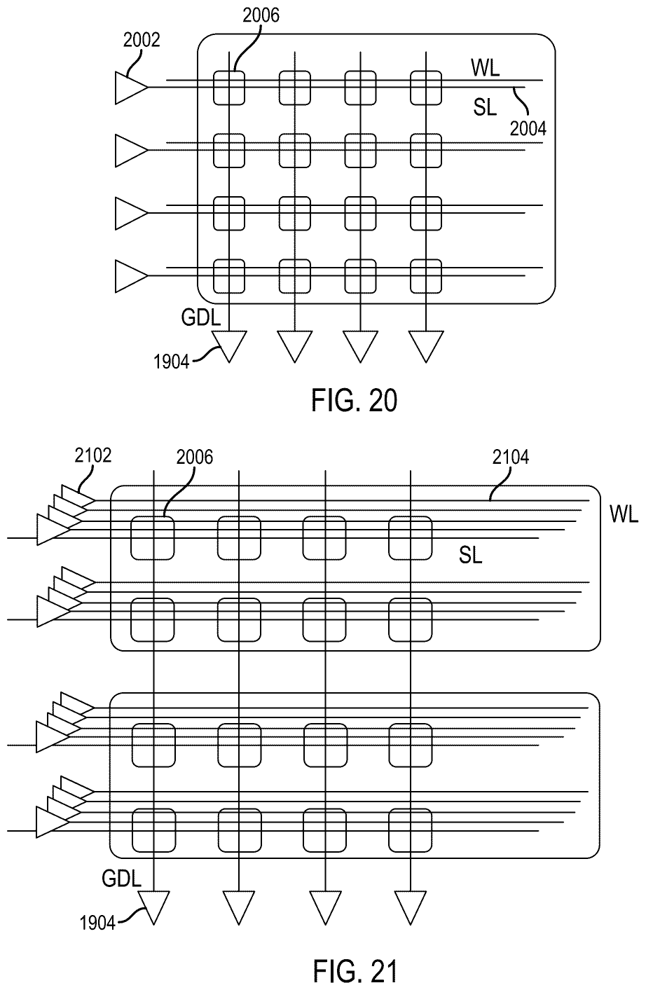

FIGS. 20-21 show top views of the memory array of FIG. 19 according to various embodiments. In FIG. 20, drivers 2002 apply voltages to select lines 2004 to select pillars 2006. In FIG. 21, drivers 2102 apply voltages to wordlines 2104 to select tiers of memory cells in pillars 2006.

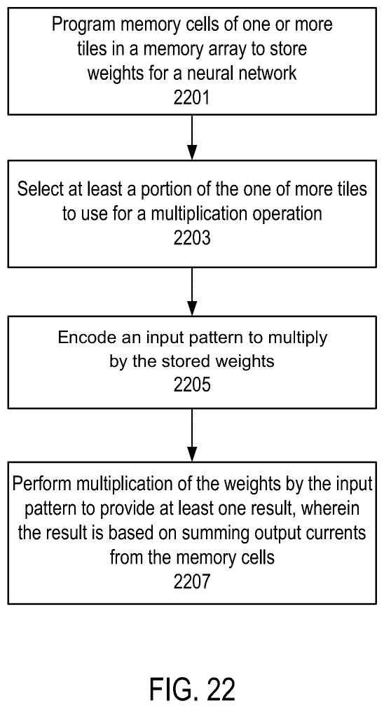

FIG. 22 shows a method for performing multiplication using memory cells located in a selected portion of one or more tiles according to one embodiment. For example, the method of FIG. 22 can be performed in integrated circuit device 101 of FIG. 1 when performing multiplication (e.g., as described in various embodiments above).

The method of FIG. 22 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 22 is performed at least in part by one or more processing devices (e.g., controller 124 of FIG. 1).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 2201, memory cells of one or more tiles in a memory array are programmed to store weights for a neural network. In one example, the memory cells are in memory cell array 113.

At block 2203, a portion (or all) of the tiles is selected to use for a multiplication operation. In one example, a portion of tiles 1202, 1912 is selected.

At block 2205, an input pattern is encoded for multiplying by the stored weights. In one example, the input pattern is time-sliced. In one example, the input pattern is applied to select line 808. In one example, the input pattern is applied to wordline 816.

At block 2207, multiplication of the weights by the input pattern is performed to provide one or more results. Each result is based on summing output currents from selected memory cells. In one example, the results are provided by accumulation circuitry (e.g., 1230).

In one embodiment, a device comprises: a memory cell array (e.g., 113) having memory cells stacked vertically, each memory cell configured to store a weight for use in a multiplication; local digit lines (e.g., 826) connected to terminals of the memory cells, the local digit lines extending vertically; select transistors (e.g., transistor having silicon layer 812) connected to the local digit lines; select lines (e.g., 808) configured to control the select transistors, and to encode an input pattern to multiply by the stored weights (e.g., Case1 above); and accumulation circuitry (e.g., 1230) configured to accumulate output currents from the memory cells to determine a result of the multiplication.

In one embodiment, the device further comprises global digit lines (e.g., 804, 1204) running horizontally in a direction orthogonal to the select lines. The select transistors connect the global digit lines to the local digit lines, and the global digit lines are used to accumulate the output currents.

In one embodiment, the device further comprises wordlines (e.g., 816) connected to gates of the memory cells. The wordlines are configured to select at least a portion of the array for use in the multiplication.

In one embodiment, the wordlines run horizontally in a direction parallel to the select lines.

In one embodiment, the memory cells of the array are arranged in horizontal tiers that are stacked vertically, and the wordlines are further configured to select at least one tier for the multiplication.

In one embodiment, the memory cells are arranged in vertical pillars, and each select transistor is located above the memory cells of a respective pillar.

In one embodiment, the local digit lines are first local digit lines, the terminals are first terminals, and the select transistors are first select transistors. The device further comprises: second local digit lines (e.g., 822) connected to second terminals of the memory cells, the second local digit lines extending vertically; and second select transistors connected to the second local digit lines, wherein each second select transistor is located below the memory cells of a respective pillar.

In one embodiment, each memory cell is configured to store multiple bits (e.g., a triple level cell (TLC)).

In one embodiment, an apparatus comprises: a memory cell array having memory cells stacked vertically, each memory cell configured to store a weight for use in a multiplication, and each memory cell having a current channel (e.g., channel provided by semiconductor layer 820) extending in a horizontal direction; wordlines connected to gates of the memory cells, wherein the wordlines are configured to encode an input pattern to multiply by the stored weights (e.g., Case2 above); and accumulation circuitry configured to accumulate output currents from the memory cells to determine a result of the multiplication.

In one embodiment, the apparatus further comprises: local digit lines connected to terminals of the memory cells, the local digit lines (e.g., 708, 826, 1214) extending vertically; select transistors (e.g., 1206) connected to the local digit lines; and select lines (e.g., 1218) configured to control the select transistors to select a subset of the array for use in the multiplication (e.g., a controller uses the select lines to define the size of the physical array to use for any given multiplication).

In one embodiment, the apparatus further comprises a controller (e.g., 124) configured to dynamically select or deselect tiers of the array to map to the input pattern.

In one embodiment, the memory cells of the array are arranged in tiers that are stacked vertically, and the output currents are accumulated from multiple tiers of the array.

In one embodiment, a first memory cell in a first pillar is used to represent a least significant bit (LSB), and at least two second memory cells of the first pillar are used to represent a most significant bit (MSB) (e.g., 1500).

In one embodiment, a combined output current of the second memory cells is an integer multiple of an output current of the first memory cell (e.g., combined output current from two cells representing an MSB is twice the output current from a single cell representing an LSB).

In one embodiment, a device comprises: a semiconductor substrate; a plurality of transistors stacked vertically in pillars above the substrate, each transistor comprising a semiconductor layer to provide a channel, and a gate layer (e.g., gate stack layer 818) (e.g., ONO stack) that wraps around at least half of a circumference of the semiconductor layer; and wordlines (e.g., 816) (e.g., WL1, WL2) configured to apply gate voltages to the transistors, wherein a portion of each wordline wraps around at least half of a circumference of the gate layer of a respective transistor.

In one embodiment, the device further comprises isolation layers (e.g., 828) electrically separating wordlines of each transistor in a pillar.

In one embodiment, the channel extends in a horizontal direction relative to the substrate.

In one embodiment, the device further comprises: first local digit lines, wherein a first terminal of each transistor connects to a respective first local digit line (e.g., LDL1, LDL2 of FIG. 9); and second local digit lines, wherein a second terminal of each transistor connects to a respective second digit line (e.g., LDL1′, LDL2′ of FIG. 9).

In one embodiment, the device further comprises: local digit lines extending vertically above the substrate, wherein a first terminal of each transistor connects to a respective local digit line (e.g., LDL1, LDL2); and select transistors, wherein a respective select transistor of each pillar (e.g., 1304, 1306) is located above the memory cells of the pillar, and each select transistor is electrically connected to a respective local digit line.

In one embodiment, the device further comprises: global digit lines (e.g., 1602) (e.g., GDL), wherein each global digit line is electrically connected to a respective local digit line (e.g., 1606), and wherein each global digit line extends in a horizontal direction relative to the substrate; and accumulation circuitry configured to accumulate, using the global digit lines, output currents from selected ones of the transistors when performing a multiplication operation.

In one embodiment, the device further comprises: local digit lines, wherein a first terminal of each transistor connects to a respective local digit line (e.g., LDL1, LDL2); and a common plate, wherein a second terminal of each transistor connects to the common plate.

In one embodiment, wordlines of first memory cells are shorted together, and the first memory cells are configured to represent a most significant bit (MSB) of a weight used for matrix vector multiplication.

In one embodiment, the device further comprises: first local digit lines extending vertically above the substrate, wherein a first terminal of each transistor in a first pillar connects to a respective first local digit line (e.g., LDL1, LDL2); second local digit lines extending vertically above the substrate, wherein a second terminal of each transistor in the first pillar connects to a respective second digit line (e.g., LDL1′, LDL2′); and third local digit lines extending vertically above the substrate, wherein a first terminal of each transistor in a second pillar connects to a respective third local digit line, and wherein a second terminal of each transistor in the second pillar connects to one of the second local digit lines.

Integrated circuit devices 101 (e.g., as in FIG. 1) can be configured as a storage device, a memory module, or a hybrid of a storage device and memory module. Examples of a storage device include a solid-state drive (SSD), a flash drive, a universal serial bus (USB) flash drive, an embedded multi-media controller (eMMC) drive, a universal flash storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

The integrated circuit devices 101 (e.g., as in FIG. 1) can be installed in a computing system as a memory sub-system having an embedded image sensor and an inference computation capability. Such a computing system can be a computing device such as a desktop computer, a laptop computer, a network server, a mobile device, a portion of a vehicle (e.g., airplane, drone, train, automobile, or other conveyance), an internet of things (IoT) enabled device, an embedded computer (e.g., one included in a vehicle, industrial equipment, or a networked commercial device), or such a computing device that includes memory and a processing device.

In general, a computing system can include a host system that is coupled to one or more memory sub-systems (e.g., integrated circuit device 101 of FIG. 1). In one example, a host system is coupled to one memory sub-system.

As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

For example, the host system can include a processor chipset (e.g., processing device) and a software stack executed by the processor chipset. The processor chipset can include one or more cores, one or more caches, a memory controller (e.g., NVDIMM controller), and a storage protocol controller (e.g., PCIe controller, SATA controller). The host system uses the memory sub-system, for example, to write data to the memory sub-system and read data from the memory sub-system.

The host system can be coupled to the memory sub-system via a physical host interface. Examples of a physical host interface include, but are not limited to, a serial advanced technology attachment (SATA) interface, a peripheral component interconnect express (PCIe) interface, a universal serial bus (USB) interface, a fibre channel, a serial attached SCSI (SAS) interface, a double data rate (DDR) memory bus interface, a small computer system interface (SCSI), a dual in-line memory module (DIMM) interface (e.g., DIMM socket interface that supports double data rate (DDR)), an open NAND flash interface (ONFI), a double data rate (DDR) interface, a low power double data rate (LPDDR) interface, a compute express link (CXL) interface, or any other interface. The physical host interface can be used to transmit data between the host system and the memory sub-system. The host system can further utilize an NVM express (NVMe) interface to access components (e.g., memory devices) when the memory sub-system is coupled with the host system by the PCIe interface. The physical host interface can provide an interface for passing control, address, data, and other signals between the memory sub-system and the host system. In general, the host system can access multiple memory sub-systems via a same communication connection, multiple separate communication connections, or a combination of communication connections.

The processing device of the host system can be, for example, a microprocessor, a central processing unit (CPU), a processing core of a processor, an execution unit, etc. In some instances, the controller can be referred to as a memory controller, a memory management unit, or an initiator. In one example, the controller controls the communications over a bus coupled between the host system and the memory sub-system. In general, the controller can send commands or requests to the memory sub-system for desired access to memory devices. The controller can further include interface circuitry to communicate with the memory sub-system. The interface circuitry can convert responses received from the memory sub-system into information for the host system.

The controller of the host system can communicate with a controller of the memory sub-system to perform operations such as reading data, writing data, or erasing data at the memory devices, and other such operations. In some instances, the controller is integrated within the same package of the processing device. In other instances, the controller is separate from the package of the processing device. The controller or the processing device can include hardware such as one or more integrated circuits (ICs), discrete components, a buffer memory, or a cache memory, or a combination thereof. The controller or the processing device can be a microcontroller, special-purpose logic circuitry (e.g., a field programmable gate array (FPGA), an application specific integrated circuit (ASIC), etc.), or another suitable processor.

The memory devices can include any combination of the different types of non-volatile memory components and volatile memory components. The volatile memory devices can be, but are not limited to, random access memory (RAM), such as dynamic random access memory (DRAM) and synchronous dynamic random access memory (SDRAM).

Some examples of non-volatile memory components include a negative-and (or, NOT AND) (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices can include one or more arrays of memory cells such as SLCs, MLCs, TLCs, QLCs, PLCs, or any combination of such. In some embodiments, a particular memory device can include an SLC portion, an MLC portion, a TLC portion, a QLC portion, or a PLC portion of memory cells, or any combination thereof. The memory cells of the memory devices can be grouped as pages that can refer to a logical unit of the memory device used to store data. With some types of memory (e.g., NAND), pages can be grouped to form blocks.

Although non-volatile memory devices such as 3D cross-point type and NAND type memory (e.g., 2D NAND, 3D NAND) are described, the memory device can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), spin transfer torque (STT)-MRAM, conductive bridging RAM (CBRAM), resistive random access memory (RRAM), oxide based RRAM (OxRAM), negative- or (NOR) flash memory, and electrically erasable programmable read-only memory (EEPROM).

A memory sub-system controller (or controller for simplicity) can communicate with the memory devices to perform operations such as reading data, writing data, or erasing data at the memory devices and other such operations (e.g., in response to commands scheduled on a command bus by controller). The controller can include hardware such as one or more integrated circuits (ICs), discrete components, or a buffer memory, or a combination thereof. The hardware can include digital circuitry with dedicated (i.e., hard-coded) logic to perform the operations described herein. The controller can be a microcontroller, special-purpose logic circuitry (e.g., a field programmable gate array (FPGA), an application specific integrated circuit (ASIC), etc.), or another suitable processor.

The controller can include a processing device (processor) configured to execute instructions stored in a local memory. In the illustrated example, the local memory of the controller includes an embedded memory configured to store instructions for performing various processes, operations, logic flows, and routines that control operation of the memory sub-system, including handling communications between the memory sub-system and the host system.

In some embodiments, the local memory can include memory registers storing memory pointers, fetched data, etc. The local memory can also include read-only memory (ROM) for storing micro-code. While the example memory sub-system includes a controller, in another embodiment of the present disclosure, a memory sub-system does not include a controller, and can instead rely upon external control (e.g., provided by an external host, or by a processor or controller separate from the memory sub-system).

In general, the controller can receive commands or operations from the host system and can convert the commands or operations into instructions or appropriate commands to achieve the desired access to the memory devices. The controller can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices. The controller can further include host interface circuitry to communicate with the host system via the physical host interface. The host interface circuitry can convert the commands received from the host system into command instructions to access the memory devices as well as convert responses associated with the memory devices into information for the host system.

The memory sub-system can also include additional circuitry or components that are not illustrated. In some embodiments, the memory sub-system can include a cache or buffer (e.g., DRAM) and address circuitry (e.g., a row decoder and a column decoder) that can receive an address from the controller and decode the address to access the memory devices.

In some embodiments, the memory devices include local media controllers that operate in conjunction with memory sub-system controller to execute operations on one or more memory cells of the memory devices. An external controller (e.g., memory sub-system controller) can externally manage the memory device (e.g., perform media management operations on the memory device). In some embodiments, a memory device is a managed memory device, which is a raw memory device combined with a local media controller for media management within the same memory device package. An example of a managed memory device is a managed NAND (MNAND) device.

The controller or a memory device can include a storage manager configured to implement storage functions discussed above. In some embodiments, the controller in the memory sub-system includes at least a portion of the storage manager. In other embodiments, or in combination, the controller or the processing device in the host system includes at least a portion of the storage manager. For example, the controller, or the processing device can include logic circuitry implementing the storage manager. For example, the controller, or the processing device (processor) of the host system, can be configured to execute instructions stored in memory for performing the operations of the storage manager described herein. In some embodiments, the storage manager is implemented in an integrated circuit chip disposed in the memory sub-system. In other embodiments, the storage manager can be part of the firmware of the memory sub-system, an operating system of the host system, a device driver, or an application, or any combination therein.

In one embodiment, an example machine of a computer system within which a set of instructions, for causing the machine to perform any one or more of the methods discussed herein, can be executed. In some embodiments, the computer system can correspond to a host system that includes, is coupled to, or utilizes a memory sub-system or can be used to perform the operations described above. In alternative embodiments, the machine can be connected (e.g., networked) to other machines in a LAN, an intranet, an extranet, or the internet, or any combination thereof. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a personal digital assistant (PDA), a cellular telephone, a web appliance, a server, a network router, a switch or bridge, a network-attached storage facility, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system includes a processing device, a main memory (e.g., read-only memory (ROM), flash memory, dynamic random access memory (DRAM) such as synchronous DRAM (SDRAM) or Rambus DRAM (RDRAM), static random access memory (SRAM), etc.), and a data storage system, which communicate with each other via a bus (which can include multiple buses).

A processing device can be one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. A processing device can also be one or more special-purpose processing devices such as an application specific integrated circuit (ASIC), a field programmable gate array (FPGA), a digital signal processor (DSP), network processor, or the like. The processing device is configured to execute instructions for performing the operations and steps discussed herein. The computer system can further include a network interface device to communicate over the network.

The data storage system can include a machine-readable medium (also known as a computer-readable medium) on which is stored one or more sets of instructions or software embodying any one or more of the methodologies or functions described herein. The instructions can also reside, completely or at least partially, within the main memory and within the processing device during execution thereof by the computer system, the main memory and the processing device also constituting machine-readable storage media. The machine-readable medium, data storage system, or main memory can correspond to the memory sub-system.

In one embodiment, the instructions include instructions to implement functionality corresponding to the operations described above. While the machine-readable medium is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to convey the substance of their work most effectively to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

In one embodiment, a memory device includes a controller that controls voltage drivers (e.g., 203, 213, 223 of FIG. 2) and/or other components of the memory device. The controller is instructed by firmware or other software. The software can be stored on a machine-readable medium as instructions, which can be used to program the controller. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In this description, various functions and operations may be described as being performed by or caused by computer instructions to simplify description. However, those skilled in the art will recognize what is meant by such expressions is that the functions result from execution of the computer instructions by one or more controllers or processors, such as a microprocessor. Alternatively, or in combination, the functions and operations can be implemented using special-purpose circuitry, with or without software instructions, such as using application-specific integrated circuit (ASIC) or field-programmable gate array (FPGA). Embodiments can be implemented using hardwired circuitry without software instructions, or in combination with software instructions. Thus, the techniques are limited neither to any specific combination of hardware circuitry and software, nor to any particular source for the instructions executed by the data processing system.

Disjunctive language such as the phrase “at least one of X, Y, or Z,” unless specifically stated otherwise, is otherwise understood with the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A device comprising:
a memory cell array having stacked memory cells, each memory cell configured to store a weight; and
select lines configured to control select transistors, and to encode an input pattern to multiply by the stored weights.

2. The device of claim 1, further comprising:
local digit lines connected to terminals of the memory cells, the local digit lines extending vertically; and
global digit lines running horizontally in a direction orthogonal to the select lines, wherein the select transistors connect the global digit lines to the local digit lines, and the global digit lines are used to accumulate output currents from the memory cells.

3. The device of claim 1, further comprising wordlines connected to gates of the memory cells, wherein the wordlines are configured to select at least a portion of the array for use in multiplication.

4. The device of claim 3, wherein the wordlines run horizontally in a direction parallel to the select lines.

5. The device of claim 3, wherein the memory cells of the array are arranged in horizontal tiers that are stacked vertically, and the wordlines are further configured to select at least one tier for the multiplication.

6. The device of claim 1, wherein the memory cells are arranged in vertical pillars, and each select transistor is located above the memory cells of a respective pillar.

7. The device of claim 6, wherein the select transistors are first select transistors, the device further comprising:
first local digit lines connected to first terminals of the memory cells, the first local digit lines extending vertically;
second local digit lines connected to second terminals of the memory cells, the second local digit lines extending vertically; and
second select transistors connected to the second local digit lines, wherein each second select transistor is located below the memory cells of a respective pillar.

8. The device of claim 1, wherein each memory cell is configured to store multiple bits.

9. An apparatus comprising:
a memory cell array having memory cells arranged vertically, each memory cell configured to store a weight, and each memory cell having a current channel extending in a horizontal direction; and
wordlines connected to gates of the memory cells, wherein the wordlines are configured to encode an input to multiply by the stored weights.

10. The apparatus of claim 9, further comprising:
local digit lines connected to terminals of the memory cells, the local digit lines extending vertically;
select transistors connected to the local digit lines; and
select lines configured to control the select transistors to select a subset of the array for use in multiplication.

11. The apparatus of claim 9, further comprising a controller configured to dynamically select or deselect tiers of the array to map to the input.

12. The apparatus of claim 9, wherein the memory cells of the array are arranged in tiers that are stacked vertically, and output currents from the memory cells are accumulated from multiple tiers of the array.

13. The apparatus of claim 12, wherein a first memory cell in a first pillar is used to represent a least significant bit (LSB), and at least two second memory cells of the first pillar are used to represent a most significant bit (MSB).

14. The apparatus of claim 13, wherein a combined output current of the second memory cells is an integer multiple of an output current of the first memory cell.

15. A device comprising:
a plurality of transistors, each transistor comprising a semiconductor layer to provide a channel, and a gate layer that wraps around the semiconductor layer; and
wordlines configured to apply gate voltages to the transistors, wherein a portion of each wordline wraps around the gate layer of a respective transistor.

16. The device of claim 15, further comprising isolation layers electrically separating wordlines of each transistor in a pillar.

17. The device of claim 15, wherein the transistors are configured above a semiconductor substrate, and the channel extends in a horizontal direction relative to the substrate.

18. The device of claim 15, further comprising:
first local digit lines, wherein a first terminal of each transistor connects to a respective first local digit line; and
second local digit lines, wherein a second terminal of each transistor connects to a respective second digit line.

19. The device of claim 15, wherein the transistors are arranged in pillars, the device further comprising:
local digit lines extending vertically above a semiconductor substrate, wherein a first terminal of each transistor connects to a respective local digit line; and
select transistors, wherein a respective select transistor of each pillar is located above the transistors of the pillar, and each select transistor is electrically connected to a respective local digit line.

20. The device of claim 19, further comprising:
global digit lines, wherein each global digit line is electrically connected to a respective local digit line, and wherein each global digit line extends in a horizontal direction relative to the substrate; and
accumulation circuitry configured to accumulate, using the global digit lines, output currents from selected ones of the transistors when performing a multiplication operation.
